(19) United States
(12) Patent Application Publication
(10) Pub. No.: US 2026/0005129 A1
(43) Pub. Date: Jan. 1, 2026

(54) SEMICONDUCTOR DEVICE AND METHODS OF FORMATION

(71) Applicant: Taiwan Semiconductor Manufacturing Company, Ltd., Hsinchu (TW)

(72) Inventor: Bo-Ruei LIN, Tainan City (TW)

(21) Appl. No.: 18/754,425

(22) Filed: Jun. 26, 2024

(51) Int. Cl. H01L 23/522

(52) U.S. Cl. CPC H01L 23/5223; H10D 1/042; H10D 1/716

(57) ABSTRACT

A trench for a trench capacitor structure is formed to have a non-uniform top view width along the length of the trench. The non-uniform top view width results in the sidewalls of the trench having a zig-zag arrangement, a semi-circular or curved arrangement, or another non-straight-lined arrangement along the length of the trench. This provides a greater amount of surface area along the sidewalls for the electrode layers and insulator layer of the trench capacitor structure, thereby increasing the capacitance of the trench capacitor structure.

### BACKGROUND

A semiconductor device may include one or more capacitor structures in an interconnect layer (e.g., a back end of line (BEOL) region or back end region) above a device layer. A capacitor structure may perform and/or support one or more functions in the semiconductor device, such as memory (e.g., dynamic random access memory (DRAM)), charge decoupling, analog-to-digital (A/D) conversion, and/or other functions.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example semiconductor device described herein.

FIGS. 2A-2C are diagrams of an example implementation of a trench capacitor structure described herein.

FIGS. 3A-3E are diagrams of an example implementation of forming a semiconductor device described herein.

FIGS. 4A-4Q are diagrams of an example implementation of forming a trench capacitor structure described herein.

FIGS. 5A-5K are diagrams of an example implementation of forming a trench capacitor structure described herein.

FIGS. 6A-6C are diagrams of an example implementation of a trench capacitor structure described herein.

FIGS. 7A and 7B are diagrams of an example implementation of a trench capacitor structure described herein.

FIG. 8 is a flowchart of an example process associated with forming a trench capacitor structure described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A capacitor structure may include a metal-insulator-metal (MIM) structure in which an insulator layer is sandwiched between two conductive electrode layers. The capacitance of the capacitor structure (e.g., the amount of charge that can be stored by the capacitor structure) is directly dependent on the geometry of the conductive electrode layers of the capacitor structure. The greater the area of the conductive electrode layers, the greater the capacitance of the capacitor structure. Thus, increasing the size of the metal electrode layers may increase the capacitance of the capacitor structure.

Increasing a lateral size of the capacitor structure is in direct contention with semiconductor design principles in the semiconductor industry, in which reducing semiconductor device sizes is pursued to achieve reduced power consumption, to achieve greater operating performance and efficiencies, and/or to enable semiconductor devices to be used in increasingly smaller form factor applications. Thus, in some cases, the size of a capacitor structure may be increased in a vertical direction in a semiconductor device such that the capacitor structure extends through a plurality of layers in the semiconductor device. A deep trench capacitor (DTC) is a type of capacitor structure that is formed in a deep trench in a semiconductor device such that the electrode layers and insulator layer extend along, and conform to, a profile of the deep trench. This enables the area of the conductive electrode layers to be increased (which increases the capacitance) with minimal increase in the lateral size of the capacitor structure.

In some implementations described herein, a trench for a trench capacitor structure (e.g., a DTC structure) is formed to have a non-uniform top view width along the length of the trench. The non-uniform top view width results in the sidewalls of the trench having a zig-zag arrangement, a semi-circular or curved arrangement, or another non-straight-lined arrangement along the length of the trench. This provides a greater amount of surface area along the sidewalls for the electrode layers and insulator layer of the trench capacitor structure, thereby increasing the capacitance of the trench capacitor structure. In some implementations, the trench capacitor structure may include a plurality of trenches that each have a non-uniform top view width, and the arrangement of the trenches as well as the arrangement of the sidewalls of the trenches provide further increases in capacitance while maintaining minimum spacing between the trenches and without increasing (or with minimal increase to) the lateral footprint of the trench capacitor structure. The trenches of the trench capacitor structure may be formed to have non-uniform top view widths using various masking and etch techniques described herein.

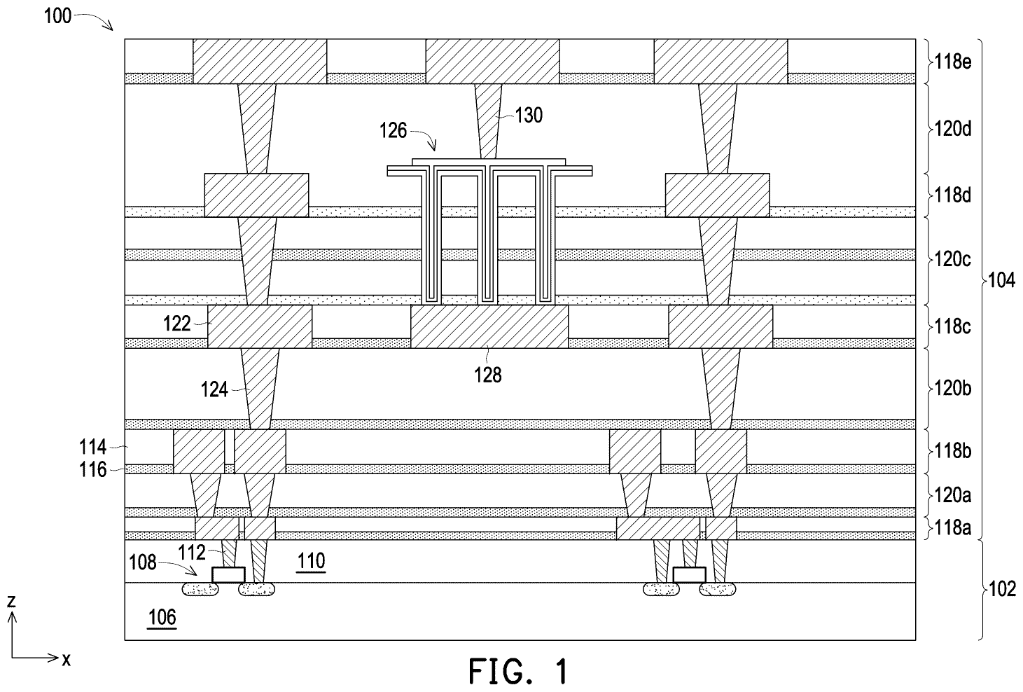

FIG. 1 is a diagram of an example semiconductor device 100 described herein. The semiconductor device 100 may include a system on chip (SoC) device, a logic device such as a central processing unit (CPU) or a graphics processing unit (GPU), a memory device (e.g., a high bandwidth memory (HBM) device), an image sensor device (e.g., a complementary metal-oxide-semiconductor (CMOS) image sensor device), and/or another type of semiconductor device.

FIG. 1 illustrates a cross-section view of the semiconductor device 100. As shown in FIG. 1, the semiconductor device 100 may include a device layer 102 and an interconnect layer 104 arranged in a z-direction in the semiconductor device 100 the device layer 102. For example, the interconnect layer 104 may be located above the device layer 102. As another example, the interconnect layer 104 may be located below the device layer 102.

The device layer 102 may also be referred to as a front end region or front end of line (FEOL) region of the semiconductor device 100. The interconnect layer 104 may also be referred to a back end region or back end of line (BEOL) region of the semiconductor device 100, and may include conductive structures that are arranged to carry signals and/or provide power distribution throughout the semiconductor device 100. In some implementations, the semiconductor device 100 includes interconnect layers 104 above and below the device layer 102. A first interconnect layer 104 on a first side of the device layer 102 may be used for signal propagation throughout the semiconductor device 100, and a second interconnect layer 104 on an opposing second side of the device layer 102 may be used for power distribution in the semiconductor device 100.

The device layer 102 includes a substrate 106 of the semiconductor device 100. The substrate 106 may correspond to a portion of a semiconductor wafer on which the semiconductor device 100 is formed. The substrate 106 may include a silicon (Si) substrate, a substrate formed of a material including silicon, a III-V compound semiconductor material substrate such as gallium arsenide (GaAs), a silicon on insulator (SOI) substrate, or another type of substrate. The substrate 106 may extend in an x-direction and/or in a y-direction in the semiconductor device 100 such that the top and bottom surfaces of the substrate 106 are approximately orthogonal to the z-direction in the semiconductor device 100.

Integrated circuit devices 108 may be included in and/or on the substrate 106 in the device layer 102 of the semiconductor device 100. The integrated circuit devices 108 may include front end transistor structures (e.g., front end planar transistor structures, front end fin field effect transistor (finFET) structures, front end gate all around (GAA) transistor structures), pixel sensors, capacitors, resistors, inductors, photodetectors, transceivers, transmitters, receives, optical circuits, and/or other types of front end semiconductor devices.

A front end transistor structure may include a plurality of source/drain regions, which may correspond to doped regions of the substrate 106, separated by a channel region in the substrate 106. In some implementations, the source/drain regions are doped with a first type of dopant (e.g., a p-type dopant such as boron (B) and/or gallium (Ga), an n-type dopant such as phosphorous (P) and/or arsenic (As)), and the channel region is doped with a second type of dopant that is different from the first type of dopant. The front end transistor structure may include a gate structure over and/or around the channel region. A gate dielectric layer of the front end transistor structure may be included between the gate structure and the channel region. The gate structure may include a polysilicon gate, a metal gate with a high dielectric constant (high-k) gate dielectric layer such as hafnium oxide (HfOₓ such as HfO₂), and/or another type of gate structure.

A dielectric layer 110 is included over the substrate 106. The dielectric layer 110 includes an interlayer dielectric (ILD) layer, an etch stop layer (ESL), and/or another type of dielectric layer. The dielectric layer 110 includes dielectric material(s) that enable various portions of the substrate 106 and/or the integrated circuit devices 108 to be selectively etched or protected from etching, and/or to electrically isolate the integrated circuit devices 108 in the device layer 102. The dielectric layer 110 includes a silicon nitride (SiₓN_{y}), an oxide (e.g., a silicon oxide (SiOₓ) and/or another oxide material), and/or another type of dielectric material. The dielectric layer 110 may extend in the x-direction and/or in the y-direction in the semiconductor device 100. Contacts 112 (e.g., source/drain contacts, gate contacts) may extend through the dielectric layer 110 and between the integrated circuit devices 108 and the interconnect layer 104. The contacts may electrically connect the integrated circuit devices 108 to the interconnect layer 104. The contacts 112 may include vias, plugs, and/or another type of elongated electrically conductive structures. The contacts 112 may include tungsten (W), cobalt (Co), ruthenium (Ru), titanium (Ti), aluminum (Al), and/or gold (Au), among other electrically conductive materials.

The interconnect layer 104 includes a plurality of dielectric layers (e.g., back end dielectric layers) that are arranged in a direction (e.g., the z-direction) that is approximately perpendicular to the top surface of the substrate 106. The dielectric layers may include ILD layers 114 and ESLs 116 that are arranged in an alternating manner in the z-direction. The ILD layers 114 and the ESLs 116 may extend in the x-direction and/or in the y-direction in the semiconductor device 100.

The ILD layers 114 may each include a low dielectric constant (low-k) oxide material such as silicon oxide (SiOₓ) or undoped silicate glass (USG). Additionally and/or alternatively, the ILD layers 114 may each include a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 114 includes an extreme low dielectric constant (ELK) dielectric material having a dielectric constant that is less than approximately 2.5. Examples of ELK dielectric materials include carbon doped silicon oxide (C-SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous HSQ, porous methyl silsesquioxane (MSQ), porous polyarylether (PAE), and/or porous silicon oxide (SiOₓ), among other examples.

The ESLs 116 may each include a silicon nitride (SiₓN_{y}), silicon carbide (SIC), silicon oxynitride (SiON), and/or another suitable dielectric material. In some implementations, an ILD layer 114 and an ESL 116 include different dielectric materials to provide etch selectivity to enable various structures to be formed in the interconnect layer 104. For example, the ILD layers 114 may each include a low-k dielectric material such as USG, and the ESLs 116 may each include a high-k dielectric material such as silicon nitride (SiₓN_{y}) or silicon carbide (SIC). Additionally and/or alternatively, two or more ESLs 116 may include different materials. For example, one or more first ESLs 116 may include silicon nitride (SiₓN_{y}), and one or more second ESLs 116 may include silicon carbide (SIC).

The interconnect layer 104 includes a plurality of conductive structures that are arranged in a plurality of layers. The conductive structures may be electrically coupled and/or physically coupled with one or more of the integrated circuit devices 108 in the device layer 102. The conductive structures provide electrical routing that enables signals and/or power to be provided to and/or from the integrated circuit devices 108.

The layers of conductive structures may include a plurality of layers 118a-118e that are vertically arranged and alternate with a plurality of layers 120a-120d in the z-direction (e.g., vertically alternate). The layers 118a-118e each include a layer of metallization structures 122, and the layers 120a-120d each include a layer of interconnect structures 124.

The layers 118a-118e of metallization structures 122 may be referred to as M-layers. For example, a layer 118a of metallization structures 122 (referred to as a metal-0 (M0) layer) may be located at the bottom of the interconnect layer 104 and may be coupled with the device layer 102. In particular, the metallization structures 122 in the M0 layer may be coupled with the contacts 112 (e.g., a contact layer referred to as “CO”-layer) of the integrated circuit devices 108 in the device layer 102. A layer 118b of metallization structures 122 (referred to as a metal-1 layer (M1) layer) may be located above the layer 118a of metallization structures 122 in the interconnect layer 104, a layer 118c of metallization structures 122 (referred to as a metal-2 layer (M2) layer) may be located above the a layer 118b of metallization structures 122, and so on.

A layer 120a of interconnect structures 124 (referred to as a via-1 (V0) layer) may be included between the M0 layer and the M1 layer to interconnect the M0 layer and the M1 layer, a layer 120b of interconnect structures 124 (referred to as a via-2 (V1) layer) may be included between the M1 layer and the M2 layer to interconnect the M1 layer and the M2 layer, and so on.

The metallization structures 122 may include a combination of trenches, metallization layers, conductive traces, and/or other types of conductive structures. The interconnect structures 124 may include a combination of vias, interconnects, and/or other types of conductive structures. The metallization structures 122 and the interconnect structures 124 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included between the dielectric layers of the interconnect layer 104 and the metallization structures 122, and/or between the dielectric layers of the interconnect layer 104 the interconnect structures 124. The one or more liner layers may include barrier liners, adhesion liners, and/or another type of liners. Examples of materials for the one or more liners include tantalum nitride (TaN) and/or titanium nitride (TiN), among other examples.

In some implementations, the topmost layer of conductive structures (e.g., a topmost layer of metallization structures 122, a topmost layer of interconnect structures 124) may be coupled to connection structures at the top of the semiconductor device 100. The connection structures may include solder balls, solder bumps, contact pads (e.g., land grid array (LGA) pads), contact pins (e.g., pin grid array (PGA) pins), under bump metallization (UBM) connections, microbumps, ball grid array (BGA) balls, controlled collapse chip connection (C4) bumps, and/or other types of connection structures. In some implementations, the topmost layer of conductive structures (e.g., a topmost layer of metallization structures 122, a topmost layer of interconnect structures 124) may be coupled to bonding structures, such as bonding pads and/or bonding vias.

As further shown in FIG. 1, a trench capacitor structure 126 is included in the interconnect layer 104 of the semiconductor device 100. The trench capacitor structure 126 may extend through and/or may be included in one or more dielectric layers in the interconnect layer 104, such as one or more ILD layers 114 and/or one or more ESLs 116. In some implementations, an integrated circuit device 108 is electrically coupled to a trench capacitor structure 126 to form a memory cell (e.g., a dynamic random access memory (DRAM) cell or another type of capacitor-based memory cell) in the semiconductor device 100. In some implementations, a trench capacitor structure 126 is configured to provide charge decoupling for one or more integrated circuit devices 108. In some implementations, a trench capacitor structure 126 is configured to store a charge (e.g., a photocurrent) for an integrated circuit device 108 (e.g., a pixel sensor) in the semiconductor device 100. In some implementations, a trench capacitor structure 126 is configured to perform another function in the semiconductor device 100.

The trench capacitor structure 126 may be electrically coupled and/or physically coupled to a bottom contact 128 at a bottom of the trench capacitor structure 126, and to a top contact 130 at a top of the trench capacitor structure 126. Alternatively, the trench capacitor structure 126 may be electrically coupled and/or physically coupled to a plurality of top contacts at the top of the trench capacitor structure 126. The bottom contact 128 and the top contact 130 may each include one or more conductive structures in the interconnect layer 104, such as one or more metallization structures 122 and/or one or more interconnect structures 124, among other examples.

As indicated above, FIG. 1 is provided as an example. Other examples may differ from what is described with regard to FIG. 1.

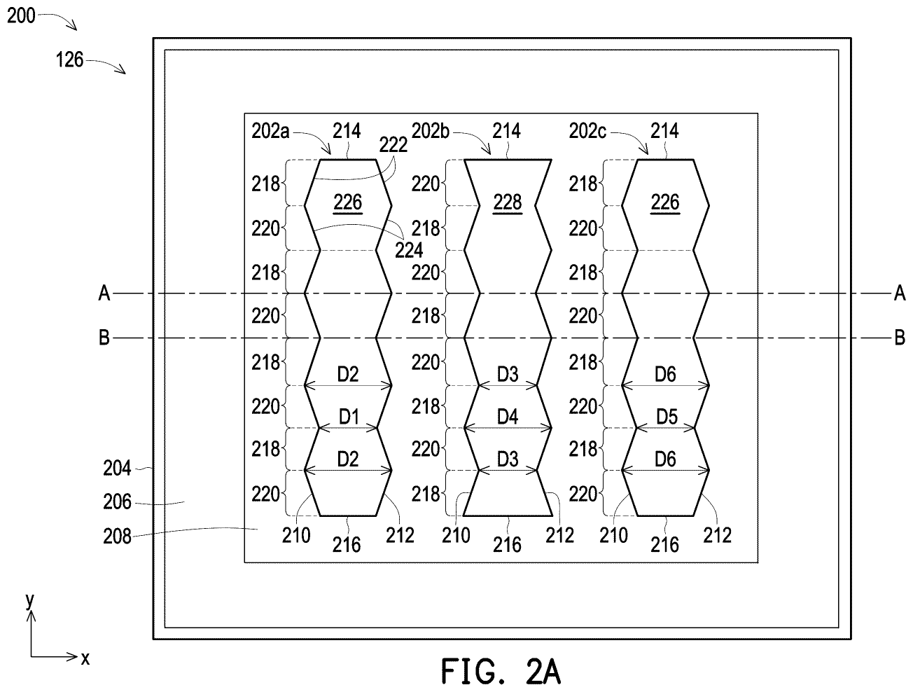

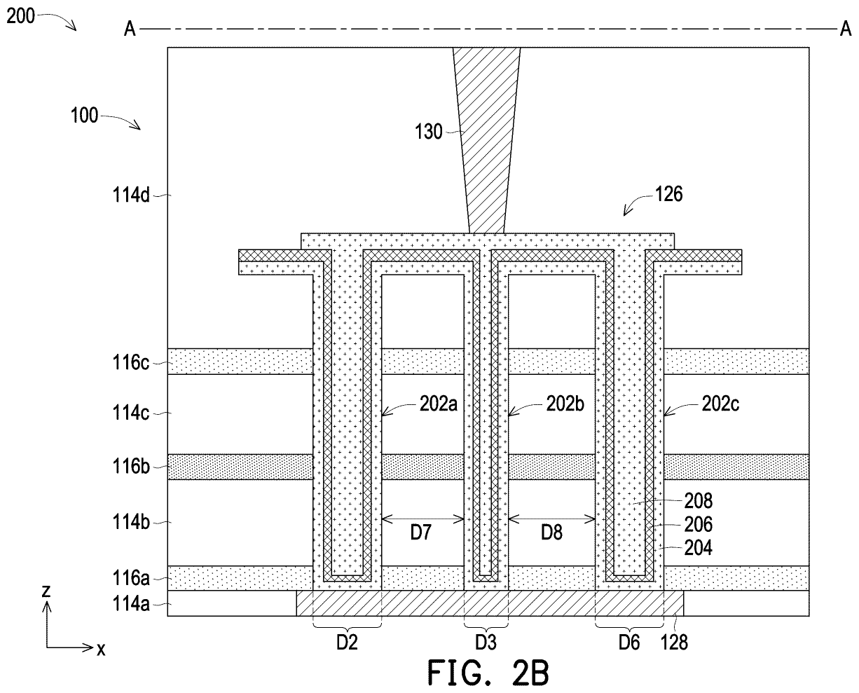

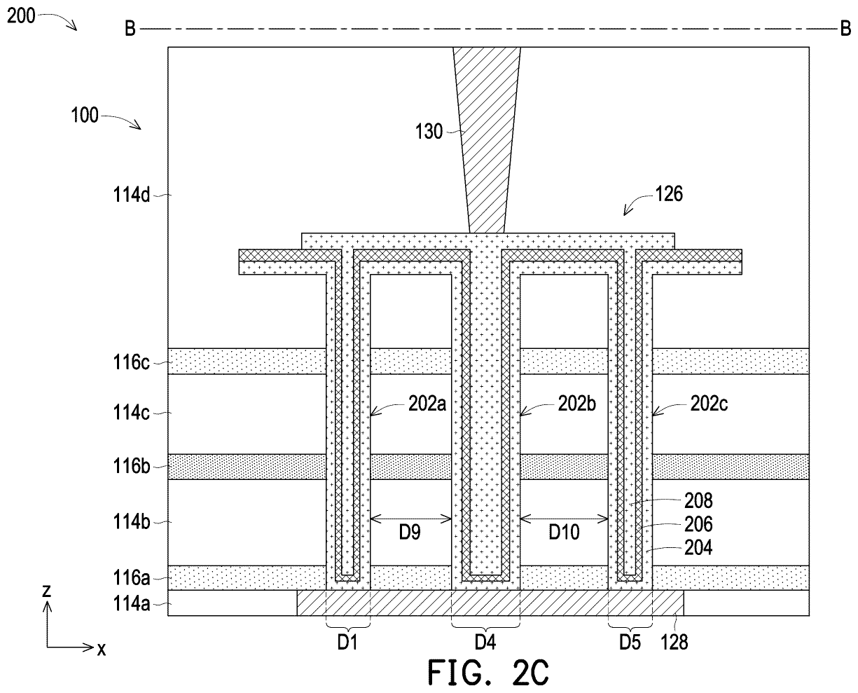

FIGS. 2A-2C are diagrams of an example implementation 200 of a trench capacitor structure 126 described herein. The example implementation 200 of the trench capacitor structure 126 may be included in the interconnect layer 104 (or another region) of the semiconductor device 100 and/or another semiconductor device. As shown in FIGS. 2A-2C, the trench capacitor structure 126 has a non-uniform width along the length of the trench capacitor structure 126, which provides increased surface area (and thus, increased capacitance) for the MIM layers of the trench capacitor structure 126. In particular, in the example implementation 200, the trench capacitor structure 126 has a zig-zag arrangement for the sidewalls of the trenches of the trench capacitor structure 126, which results in the trenches having an approximate repeating pattern of hexagon shapes in a top view of the trenches.

FIG. 2A illustrates a top view of the example implementation 200 of a trench capacitor structure 126. As shown in FIG. 2A, the trench capacitor structure 126 includes one or more trenches, such as a trench 202a, a trench 202b, and/or a trench 202c, among other examples. The quantity of trenches is an example, and other quantities of trenches for the trench capacitor structure 126 are within the scope of the present disclosure.

The trench capacitor structure 126 also includes a plurality of layers that extend in a z-direction into the trench(es) 202a-202c and extend laterally in an x-direction and/or in a y-direction in the semiconductor device 100. The layers include a bottom electrode layer 204, an insulator layer 206 on the bottom electrode layer 204, and a top electrode layer 208 on the insulator layer 206. The bottom electrode layer 204, the insulator layer 206, and the top electrode layer 208 correspond to an MIM structure of the trench capacitor structure 126. Thus, the trench capacitor structure 126 may also be referred to as an MIM capacitor structure.

The bottom electrode layer 204 (also referred to as a capacitor bottom metal (CBM)) and the top electrode layer 208 (also referred to as a capacitor top metal (CTM)) may each include one or more electrically conductive metals, one or more electrically conductive metal-containing materials, one or more electrically conductive ceramic materials, and/or other types of electrically conductive materials. Examples include tungsten (W), cobalt (Co), ruthenium (Ru), titanium (Ti), aluminum (Al), copper (Cu), gold (Au), titanium nitride (TiN), and/or tantalum nitride (TaN), among other examples. In some implementations, the bottom electrode layer 204 and the top electrode layer 208 include the same material or the same material composition. In some implementations, the bottom electrode layer 204 and the top electrode layer 208 include different materials or different material compositions.

The insulator layer 206 may include one or more electrically insulating materials. In some implementations, the insulator layer 206 includes one or more low-k dielectric materials such as silicon oxide (SiOₓ such as SiO₂). Additionally and/or alternatively, the insulator layer 206 may include one or more high-k dielectric materials such as zirconium oxide (ZrOₓ such as ZrO₂), aluminum oxide (AlₓO_{y} such as Al₂O₃), silicon nitride (SiₓN_{y} such as Si₃N₄), yttrium oxide (YₓO_{y} such as Y₂O₃), lanthanum oxide (LaₓO_{y} such as La₂O₃), and/or hafnium oxide (HfOₓ such as HfO₂), among other examples. In some implementations, the insulator layer 206 is a multiple-layer stack that includes a plurality of dielectric layers. For example, the insulator layer 206 may include a ZrO₂/Al₂O₃/ZrO₂ (ZAZ) layer stack.

In implementations in which the trench capacitor structure 126 includes a plurality of trenches 202a-202c, the MIM structure of the trench capacitor structure 126 (e.g., the bottom electrode layer 204, the insulator layer 206, and the top electrode layer 208) may extend along sidewalls 210 and 212 of the trenches 202a-202c, along bottom surfaces of the trenches 202a-202c, and continuously between the plurality of trenches 202a-202c. The trenches 202a-202c may be laterally arranged in the x-direction and spaced apart by a distance in the x-direction. The length of the trenches 202a-202c may extend in the y-direction between opposing ends 214 and 216 of the 202a-202c. Including a plurality of trenches 202a-202c in the trench capacitor structure 126 enables the area of the MIM structure of the trench capacitor structure 126 (e.g., the area of the bottom electrode layer 204, the insulator layer 206, and the top electrode layer 208) to be extended by spanning across the plurality of trenches 202a-202c, thereby increasing the capacitance of the trench capacitor structure 126.

As further shown in FIG. 2A, the trenches 202a-202c have a non-uniform x-direction width along the length (e.g., along the y-direction) of the trenches 202a-202c between the opposing ends 214 and 216. The non-uniform x-direction width is achieved through the arrangement of the sidewalls 210 and/or 212 of the trenches 202a-202c in approximate zig-zag patterns as opposed to the sidewalls 210 and/or 212 extending in a uniform straight line between the opposing ends 214 and 216. Thus, the x-direction width of the trench 202a transitions between narrow parts of the trench 202a (where the x-direction width is indicated as a dimension D1) and wide parts of the trench 202a (where the x-direction width is indicated as a dimension D2) between the ends 214 and 216. Similarly, the x-direction width of the trench 202b transitions between narrow parts of the trench 202b (where the x-direction width is indicated as a dimension D3) and wide parts of the trench 202b (where the x-direction width is indicated as a dimension D4) between the ends 214 and 216, and the x-direction width of the trench 202c transitions between narrow parts of the trench 202c (where the x-direction width is indicated as a dimension D5) and wide parts of the trench 202c (where the x-direction width is indicated as a dimension D6) between the ends 214 and 216.

The transitions between the narrowest parts and the widest parts of the trench 202a (and for the trenches 202b and 202c) may occur in sections of the trench 202a. For example, the trench 202a (and for the trenches 202b and 202c) may include a plurality of top view sections 218 and a plurality of top view sections 220. The top view sections 218 and the top view sections 220 may be arranged in an alternating manner in the y-direction between the ends 214 and 216, thereby forming a repeating pattern in the y-direction. In other words, the top view sections 218 alternate with the top view sections 220. In the repeating pattern, opposing ends of the top view sections 218 are coupled to ends of top view sections 220 laterally adjacent to the opposing ends of the top view sections 218. In other words, a top view section 218 may include a first end (e.g., at which the x-direction width of the trench 202a corresponds to the dimension D1) and an opposing second end (e.g., at which the x-direction width of the trench 202a corresponds to the dimension D1). The first end may be coupled to an end of a first top view section 220, and the second end may be coupled to an end of a second top view section 220. The top view sections 220 may be coupled to top view sections 218 in the y-direction in a similar manner.

The connection points between the top view sections 218 and the top view sections 220 may correspond to inflection points where the x-direction width of the trenches 202a-202c transition between increasing and decreasing. The top view sections 218 may increase in x-direction width along the y-direction from the ends 214 of the trenches 202a-202c toward the ends 216 of the trenches 202a-202c. Conversely, the top view sections 220 may decrease in x-direction width along the y-direction from the ends 214 of the trenches 202a-202c toward the ends 216 of the trenches 202a-202c. The top view sections 218 and the top view sections 220 may have mirrored top view shapes along the x-direction. For example, a top view section 218 may have an approximate trapezoid top view shape, and a top view section 220 may have an approximate trapezoid top view shape that is mirrored along the x-direction relative to the approximate trapezoid top view shape of the top view section 218. However, other top view shapes and arrangements are within the scope of the present disclosure.

Additionally and/or alternatively, the dimension D1 (or the dimension D3, or the dimension D5) may correspond to a widest part of the trench 202a (or of the trench 202b, or of the trench 202c), the dimension D2 (or the dimension D3, or the dimension D5) may correspond to a narrowest part of the trench 202a (or of the trench 202b, or of the trench 202c), and the trench 202a (or the trench 202b, or the trench 202c) may have additional local inflection points where the x-direction width transitions between increasing and decreasing at an x-direction width that is less than the width at the widest part of the trench 202a (or the trench 202b, or of the trench 202c) and is greater than the width of the narrowest part of the trench 202a (or the trench 202b, or of the trench 202c).

In some implementations, a difference between a widest part of the trench 202a (or of the trench 202b, or of the trench 202c) and a narrowest part of the trench 202a (or of the trench 202b, or of the trench 202c) along the length of the trench 202a in the y-direction between the ends 214 and 216 is at least approximately 10% of an average of the top x-direction width (e.g., the x-direction width at the top of the trench) along the length of the trench 202a. Having a difference in x-direction width at the top of the trench 202a that is at least approximately 10% of the average of the top x-direction width along the length of the trench 202a ensures that the area of the sidewalls 210 and 212 is sufficiently increased over uniform straight-lined sidewalls to achieve an increase in capacitance (e.g., to achieve at least an approximate 2% or greater increase in capacitance) for the trench capacitor structure 126. Similarly for the trenches 202b and 202c. However, other values are within the scope of the present disclosure.

In some implementations, the difference between the widest part of the trench 202a (or of the trench 202b, or of the trench 202c) and the narrowest part of the trench 202a (or of the trench 202b, or of the trench 202c) along the length of the trench 202a is included in a range of approximately 10 nanometers to approximately 40 nanometers, which may enable a difference in x-direction width at the top of the trench 202a of at least approximately 10% of the average of the top x-direction width along the length of the trench 202a to be achieved. For example, if the average x-direction width at the top of the trench 202a is approximately 113 nanometers, the x-direction width at the top of the trench 202a along the length of the trench 202a may have a range of approximately 103 nanometers to approximately 123 nanometers at the low end, and up to approximately 73 nanometers to approximately 153 nanometers at the high end. However, other values and ranges are within the scope of the present disclosure.

As further shown in FIG. 2A, each top view section 218 may include a plurality of top view line segments 222, and each top view section 220 may include a plurality of top view line segments 224. Thus, the sidewalls 210 and 212 of the trench 202a (or of the trench 202b, or of the trench 202c) may each include an alternating arrangement of top view line segments 222 and 224 along the length of the trench 202a in the y-direction between the opposing ends 214 and 216 of the trench 202a. The top view line segments 222 may be mirrored along the x-direction relative to the top view line segments 224. This results in the sidewalls 210 and 212 of the trench 202a (or of the trench 202b, or of the trench 202c) each having an approximate zig-zag top view profile in the y-direction.

Moreover, the alternating arrangement of top view section 218 and the top view line segments 222 in the y-direction along the length of the trench 202a results in the top view profile of the trench 202a including a plurality of repeating top view sections 226. Each top view section 226 includes a top view section 218 and an adjacent top view section 220. In the example implementation 200, the combination of the top view section 218 and the adjacent top view section 220 results in each top view section 226 having an approximate hexagonal top view shape. Thus, the top view sections 226 are convex top view sections that have convex sidewalls. The x-direction width of the trench 202a may increase from opposing ends of a top view section 226 toward a middle of the top view section 226. The trench 202c may be arranged in a similar manner. However, the trench 202b between the trench 202a and the trench 202c may have a different arrangement of top view sections than the trench 202a and the trench 202c. For example, the trench 202b may include a plurality of repeating top view sections 228 that have an irregular hexagonal top view shape. Thus, the top view sections 228 are concave top view sections that have concave sidewalls. The x-direction width of the trench 202b may decrease from opposing ends of a top view section 228 toward a middle of the top view section 228.

The trenches 202a-202c may be aligned in the y-direction such that the top view sections 218 of the trenches 202a and 202c are aligned in the y-direction with the top view sections 220 of the trench 202b. Moreover, the trenches 202a-202c may be aligned in the y-direction such that the top view sections 226 of the trenches 202a and 202c are aligned in the y-direction with the top view sections 228 of the trench 202b. Thus, the trench 202b may have an inverted top view profile relative to the top view profiles of the trenches 202a and 202c. This results in the sidewall 212 of the trench 202a and the sidewall 210 of the trench 202b having approximately a same zig-zag profile, which enables a substantially consistent and uniform distance to be maintained between the trenches 202a and 202b. Moreover, this results in the sidewall 212 of the trench 202b and the sidewall 210 of the trench 202c having approximately a same zig-zag profile, which enables a substantially consistent and uniform distance to be maintained between the trenches 202b and 202c.

FIG. 2B illustrates a detailed cross-section view of the example implementation 200 of a trench capacitor structure 126 along the line A-A in FIG. 2A. FIG. 2C illustrates a detailed cross-section view of the example implementation 200 of a trench capacitor structure 126 along the line B-B in FIG. 2A. As shown in FIGS. 2B and 2C, the trenches 202a-202c may extend in the z-direction in the semiconductor device 100 and may be included on the bottom contact 128. The bottom contact 128 may be included in an ILD layer 114a in the interconnect layer 104 of the semiconductor device 100. Trenches 202a-202c may extend through one or more dielectric layers in the interconnect layer 104 of the semiconductor device 100, including through an ESL 116a, an ILD layer 114a, an ESL 116b, an ILD layer 114c, an ESL 116c, and/or an ILD layer 114d, among other examples. In some implementations, the trenches 202a-202c may have a high aspect ratio, which is a ratio of a depth (or height) of the trenches 202a-202c to a lateral width (or critical dimension) of the trenches 202a-202c. Thus, the trench capacitor structure 126 may be referred to as a DTC structure. In some implementations, the aspect ratio of the trenches 202a-202c may be approximately 10:1 or greater. In some implementations, the trenches 202a-202c may have an aspect ratio that is included in the range of approximately 20:1 to approximately 50:1. However, other values and ranges are within the scope of the present disclosure.

As further shown in FIGS. 2B and 2C, the trench capacitor structure 126 includes a plurality of conformal layers that conform to the cross-sectional profile of the trenches 202a-202c. The conformal layers may include the bottom electrode layer 204 and the insulator layer 206 on the bottom electrode layer 204. In some implementations, an adhesion layer is included between the bottom electrode layer 204 and the sidewalls and bottom surfaces of the trenches 202a-202c. The bottom electrode layer 204 and the insulator layer 206 may each conform to the cross-sectional profile of the trenches 202a-202c such that the bottom electrode layer 204 and the insulator layer 206 conform to the sidewalls and the bottom surfaces of the trenches 202a-202c. The top electrode layer 208 may be included on the insulator layer 206. In some implementations, the top electrode layer 208 is a fill layer that fills in the remaining areas of the trenches 202a-202c. Alternatively, the top electrode layer 208 may also be a conformal layer that conforms to the sidewalls and the bottom surfaces of the trenches 202a-202c, and a dielectric plug layer or fill layer is further included in the remaining areas of the trenches 202a-202c. The top contact 130 may be included on, and in electrical and physical contact with, the top electrode layer 208.

As further shown in FIG. 2B, in the cross-section view along the line A-A, the x-direction width of the trench 202a (dimension D2 in FIG. 2B) and the x-direction width of the trench 202c (dimension D6 in FIG. 2B) are greater than the x-direction width of the trench 202b (dimension D3 in FIG. 2B). A distance between the trenches 202a and 202b (indicated in FIG. 2B as a dimension D7) and a distance between the trenches 202b and 202c (indicated in FIG. 2B as a dimension D8) may be approximately a same distance because of the trench 202b having an inverted top view profile relative to the top view profiles of the trenches 202a and 202c. Alternatively, the distance between the trenches 202a and 202b and a distance between the trenches 202b and 202c may be different distances. In some implementations, the distance between the trenches 202a and 202b and a distance between the trenches 202b and 202c may each be included in a range of approximately 145 nanometers to approximately 175 nanometers. However, other values for the range are within the scope of the present disclosure.

As further shown in FIG. 2C, in the cross-section view along the line B-B, the x-direction width of the trench 202a (dimension D1 in FIG. 2C) and the x-direction width of the trench 202c (dimension D5 in FIG. 2C) are less than the x-direction width of the trench 202b (dimension D4 in FIG. 2C). A distance between the trenches 202a and 202b (indicated in FIG. 2B as a dimension D9) and a distance between the trenches 202b and 202c (indicated in FIG. 2B as a dimension D10) may be approximately a same distance because of the trench 202b having an inverted top view profile relative to the top view profiles of the trenches 202a and 202c. Alternatively, the distance between the trenches 202a and 202b and the distance between the trenches 202b and 202c may be different distances. In some implementations, the distance between the trenches 202a and 202b and the distance between the trenches 202b and 202c may each be included in a range of approximately 145 nanometers to approximately 175 nanometers. However, other values for the range are within the scope of the present disclosure.

As indicated above, FIGS. 2A-2C are provided as an example. Other examples may differ from what is described with regard to FIGS. 2A-2C. For example, one or more of the trenches 202a-202c may have a non-uniform x-direction width that results from trench sidewalls that have a non-uniform (or non-repeating) zig-zag profile, or another type of non-uniform profile. Moreover, the top view profile of one or more of the trenches 202a-202c may have non-uniform (or non-repeating) top view sections.

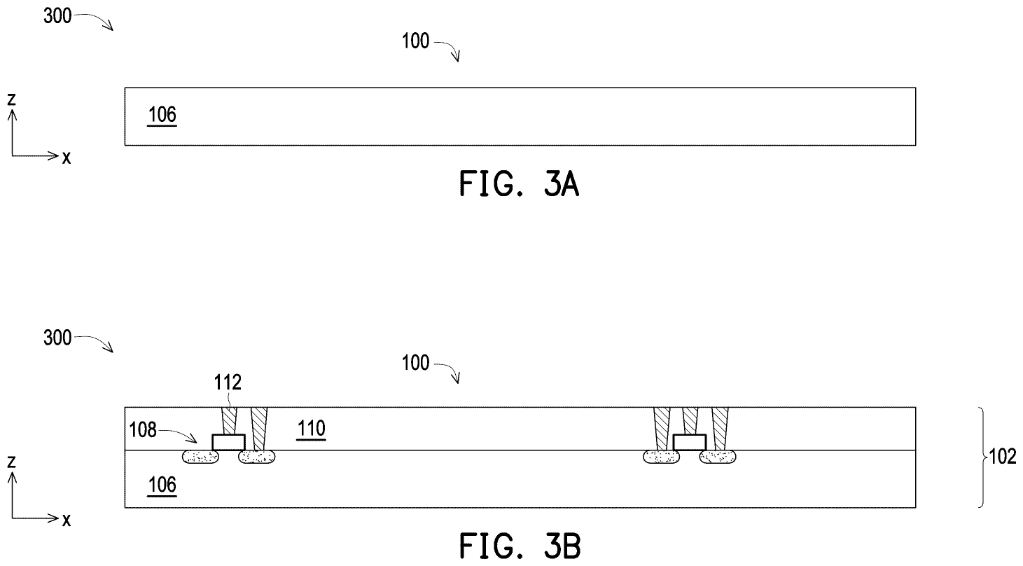

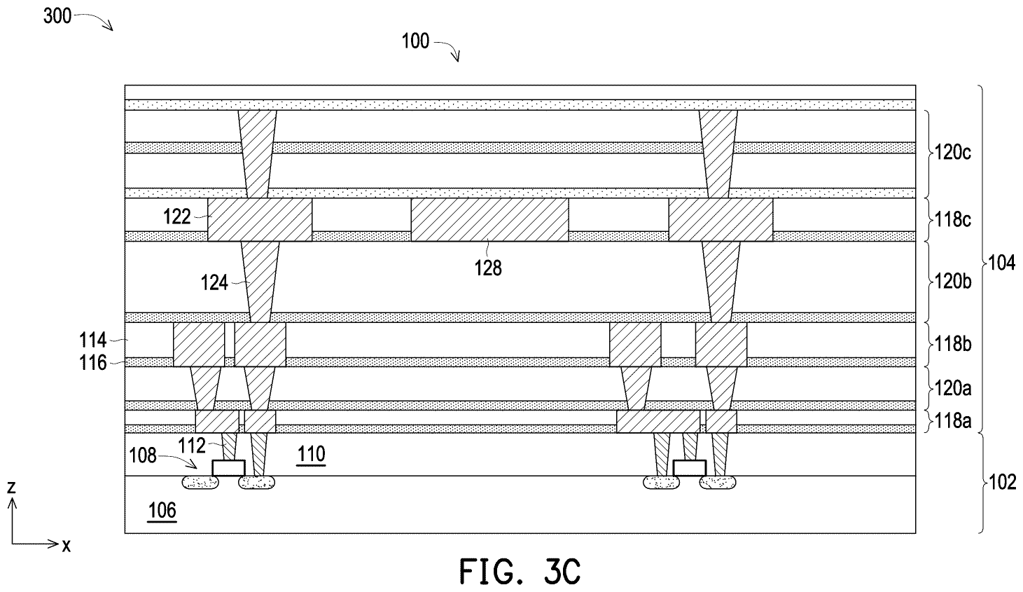

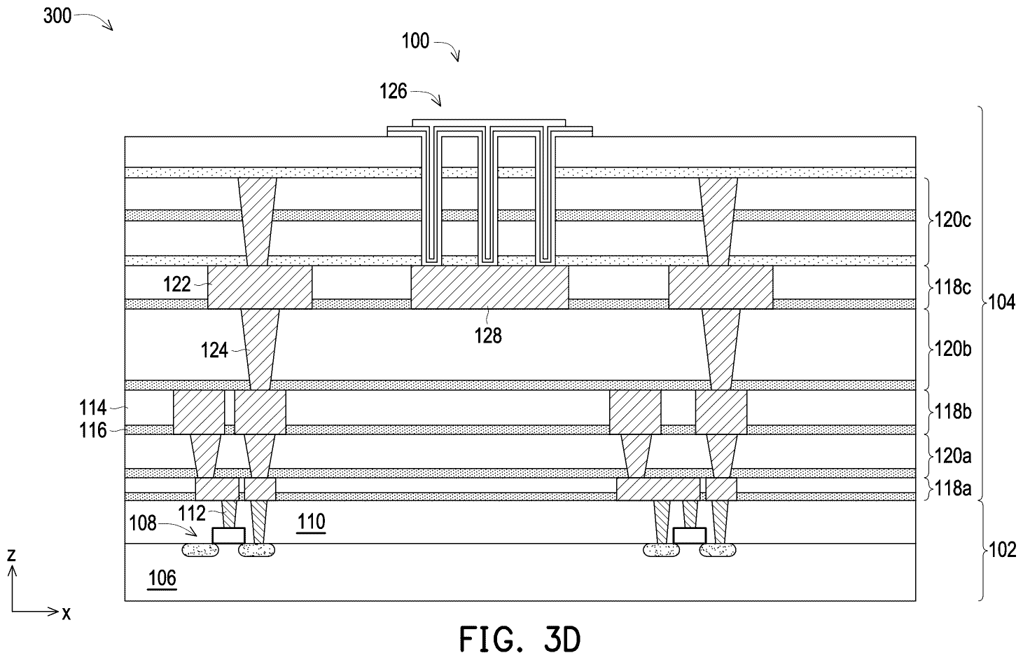

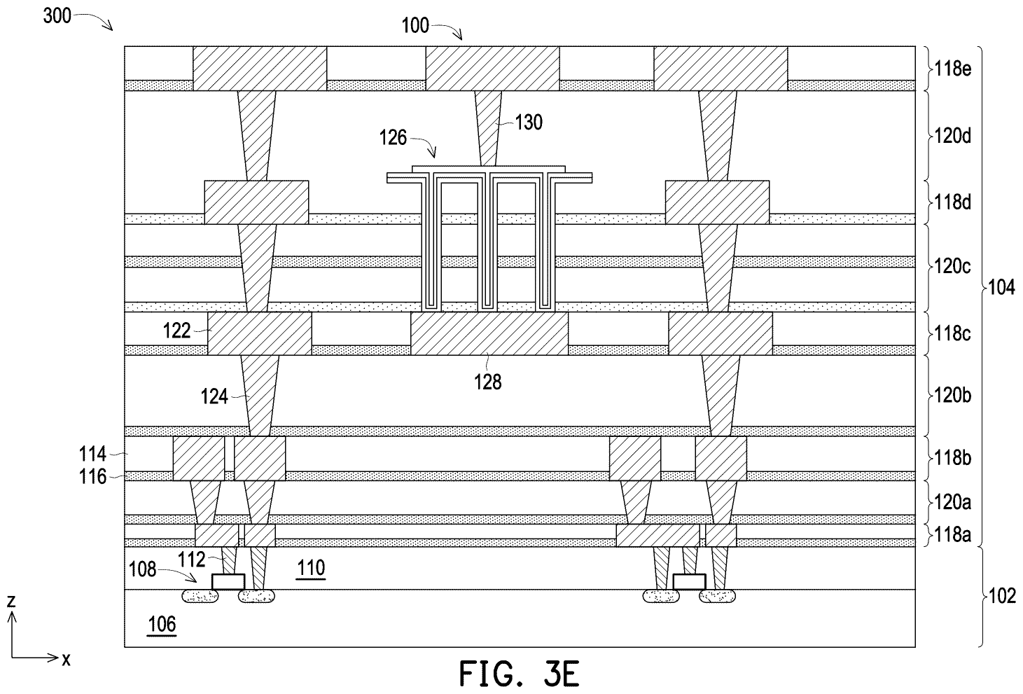

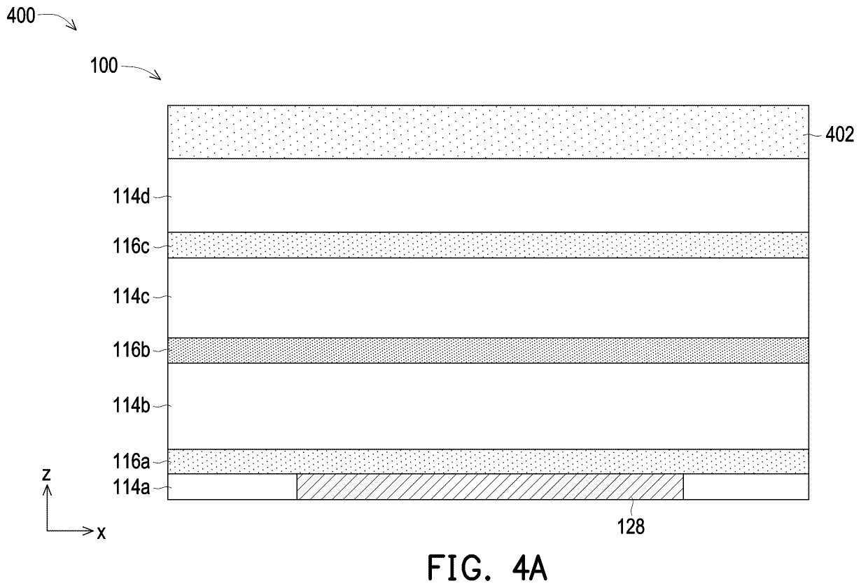

FIGS. 3A-3E are diagrams of an example implementation 300 of forming the semiconductor device 100 described herein. In some implementations, one or more of the semiconductor processing operations described in connection with FIGS. 3A-3E may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

Turning to FIG. 3A, the substrate 106 is provided. The substrate 106 may be provided in the form of a semiconductor wafer such as a silicon (Si) wafer, an SOI wafer, and/or another type of semiconductor work piece. The semiconductor device 100 may be formed on the semiconductor wafer with other semiconductor devices.

As shown in FIG. 3B, the integrated circuit devices 108 may be formed in and/or on the substrate 106 in the device layer 102 of the semiconductor device 100. One or more semiconductor processing tools may be used to form one or more portions of the integrated circuit devices 108. For example, an ion implantation tool may be used to dope one or more regions in the substrate 106 with one or more types of dopants to form well regions, implant regions, and/or other types of doped regions in the substrate 106 for the integrated circuit devices 108. As another example, a deposition tool may be used to perform various deposition operations to deposit layers and/or structures of the integrated circuit devices 108, and/or to deposit photoresist layers for etching the substrate 106 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate 106 and/or portions of the deposited layers to form the integrated circuit devices 108. As another example, a planarization tool may be used to planarize portions of the integrated circuit devices 108. As another example, a plating tool may be used to deposit metal structures and/or layers of the integrated circuit devices 108.

As further shown in FIG. 3B, a deposition tool is used to deposit the dielectric layer 110 over and/or on the substrate 106 and over and/or on the integrated circuit devices 108. A deposition tool may be used to deposit the dielectric layer 110 using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to perform a planarization operation such as a chemical mechanical planarization (CMP) operation to planarize the dielectric layer 110 after the dielectric layer 110 is deposited.

As further shown in FIG. 3B, the contacts 112 of the integrated circuit devices 108 may be formed through the dielectric layer 110. The contacts 112 may be formed in recesses in the dielectric layer 110. In some implementations, a pattern in a photoresist layer is used to etch the dielectric layer 110 to form the recesses. In these implementations, a deposition tool may be used to form the photoresist layer on the dielectric layer 110. An exposure tool may be used to expose the photoresist layer to a radiation source to pattern the photoresist layer. A developer tool may be used to develop and remove portions of the photoresist layer to expose the pattern. An etch tool may be used to etch the dielectric layer based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 110 based on a pattern to form the recesses.

The contacts 112 may be formed in the recesses. In some implementations, a contact 112 (e.g., a gate contact) is formed on a gate structure of an integrated circuit device 108. In some implementations, a contact 112 (e.g., a source/drain contact) is formed on a source/drain region of an integrated circuit device 108. A deposition tool may be used to deposit the material of the contacts 112 in the recesses using a CVD technique, a PVD technique, an ALD technique, an electroplating technique, and/or another suitable deposition technique. The material of the contacts 112 may be deposited in one or more deposition operations. In some implementations, a seed layer is first deposited, and the material of the contacts 112 is deposited on the seed layer. In some implementations, a planarization tool is used to perform a planarization operation (e.g., a CMP operation) to planarize the contacts 112 after the contacts 112 are deposited such that the tops of the contacts 112 are approximately co-planar with the top of the dielectric layer 110.

As shown in FIG. 3C, a first portion of the interconnect layer 104 of the semiconductor device 100 is formed above the dielectric layer 110. One or more deposition tools are used to deposit alternating layers of ILD layers 114 and ESLs 116 in the first portion of the interconnect layer 104 of the semiconductor device 100. In this way, the ILD layers 114 and ESLs 116 may be arranged in the z-direction in the semiconductor device 100. One or more deposition tools may be used to deposit each of the ILD layers 114 and each of the ESLs 116 using a PVD technique, an ALD technique, a CVD technique, an oxidation technique, and/or another suitable deposition technique. In some implementations, a planarization tool may be used to planarize the ILD layers 114 and/or the ESLs 116 after the ILD layers 114 and/or the ESLs 116 are deposited.

As further shown in FIG. 3C, a deposition tool, an exposure tool, a developer tool, an etch tool, a planarization tool, a plating tool, and/or another semiconductor processing tool may be used to perform various operations to form the metallization structures 122 and to form the interconnect structures 124 in the first portion of the interconnect layer 104 of the semiconductor device 100. The bottom contact 128 of the trench capacitor structure 126 may also be formed in the first portion of the interconnect layer 104.

In some implementations, the first portion of the interconnect layer 104 may be formed in a plurality of layers. For example, an ILD layer 114 and an ESL 116 may be formed (e.g., using one or more deposition tools and/or one or more planarization tools), recesses may be formed in and/or through the ILD layer 114 and the ESL 116 (e.g., using an exposure tool, a developer tool, and/or an etch tool), and the layer 118a (e.g., the M0 layer) of metallization structures 122 may be formed in the ILD layer 114 and the ESL 116 (e.g., using one or more deposition tools and/or one or more planarization tools). Another ILD layer 114 and another ESL 116 may be formed, and the layer 120a (e.g., the V0 layer) of interconnect structures 124 may be formed in the ILD layer 114 and the ESL 116. The layers 118b, 118c, 120b, and 120c may be formed in a similar manner.

One or more deposition tools may be used to deposit the metallization structures 122, the interconnect structures 124, and/or the bottom contact 128 using a PVD technique, an ALD technique, a CVD technique, an electroplating technique (e.g., an electro-chemical plating technique), and/or another suitable deposition technique. In some implementations, a planarization tool may be used to planarize the metallization structures 122, the interconnect structures 124, and/or the bottom contact 128 after the metallization structures 122, the interconnect structures 124, and/or the bottom contact 128 are deposited.

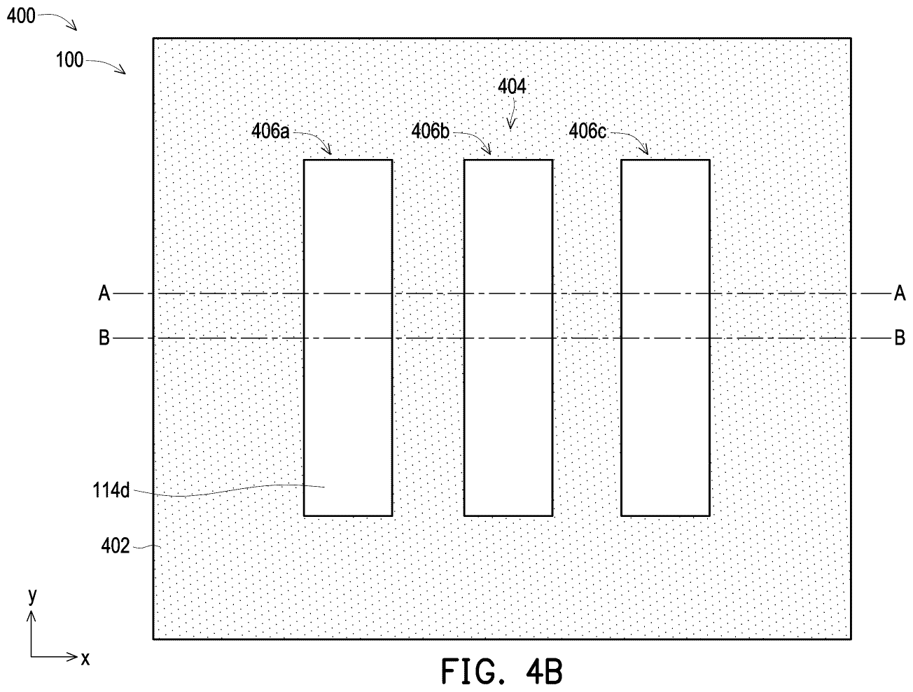

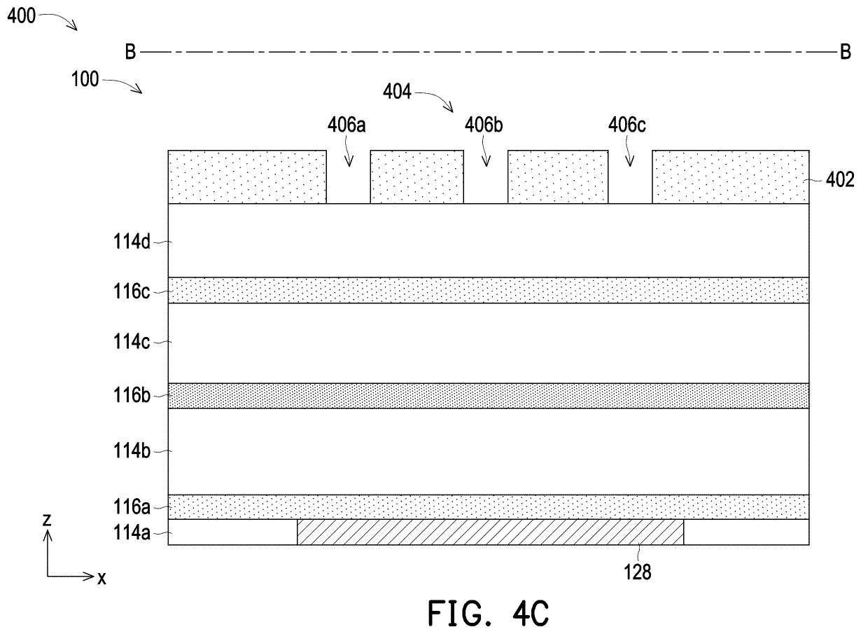

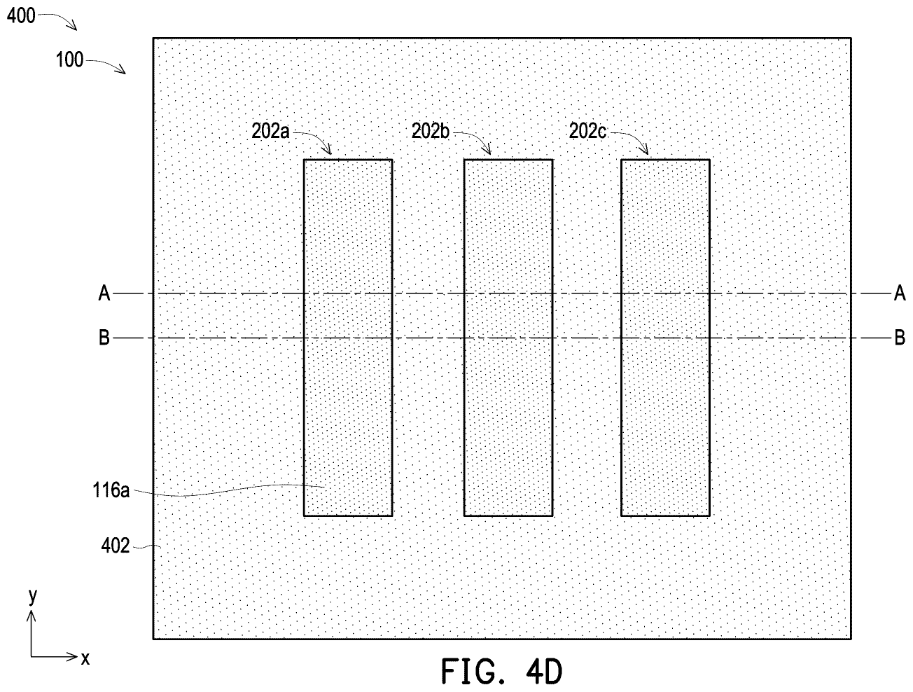

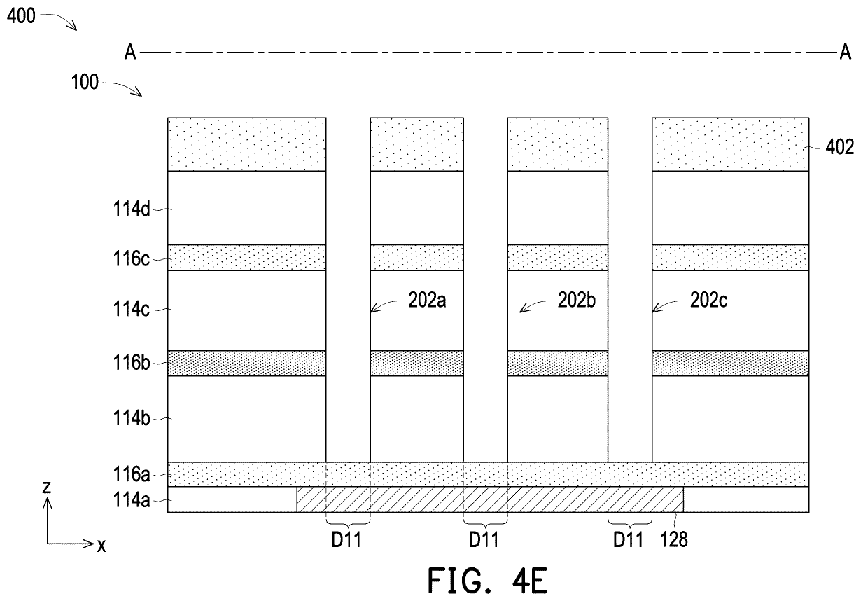

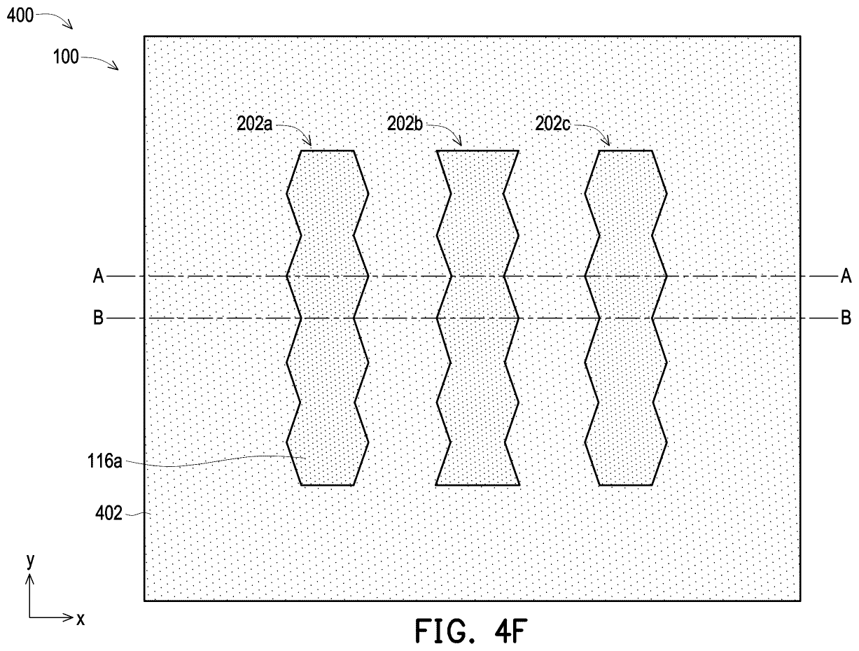

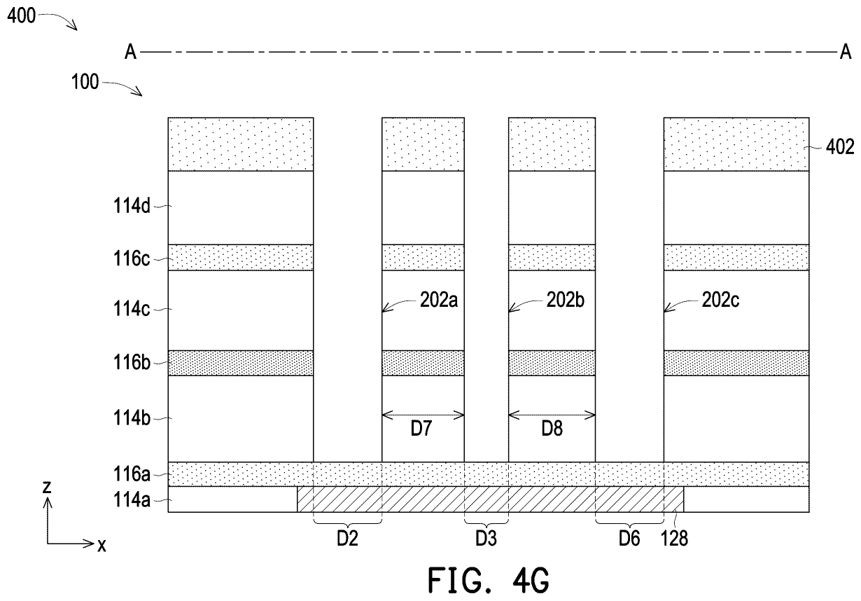

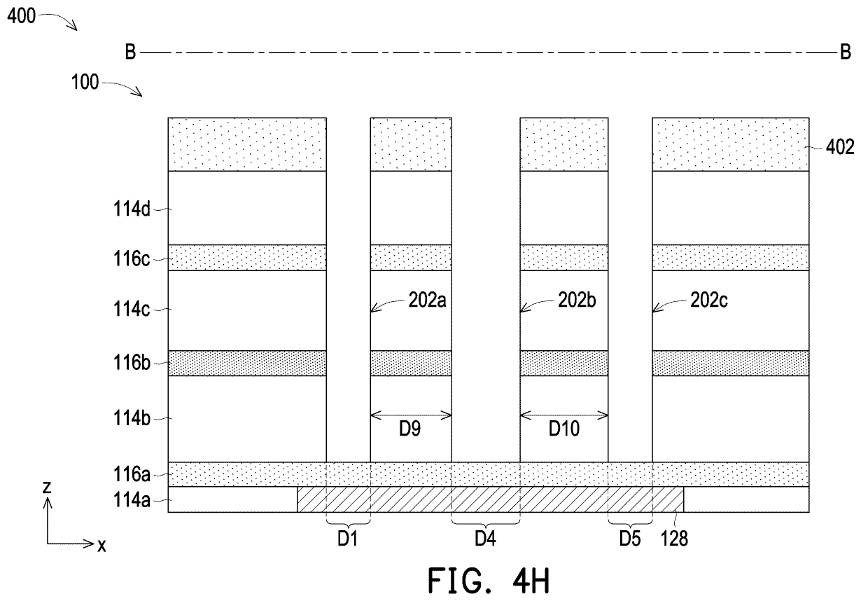

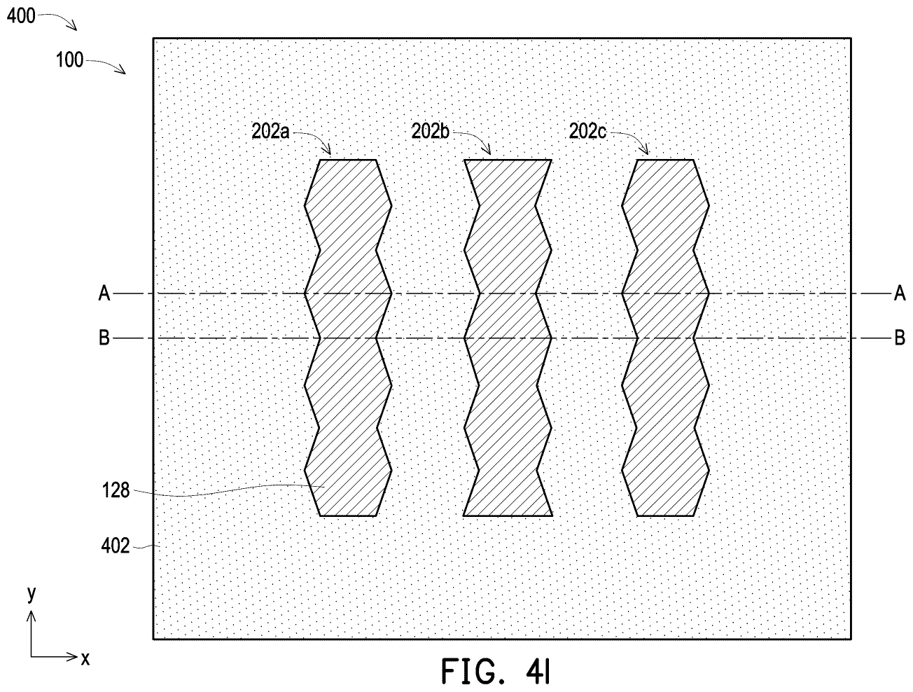

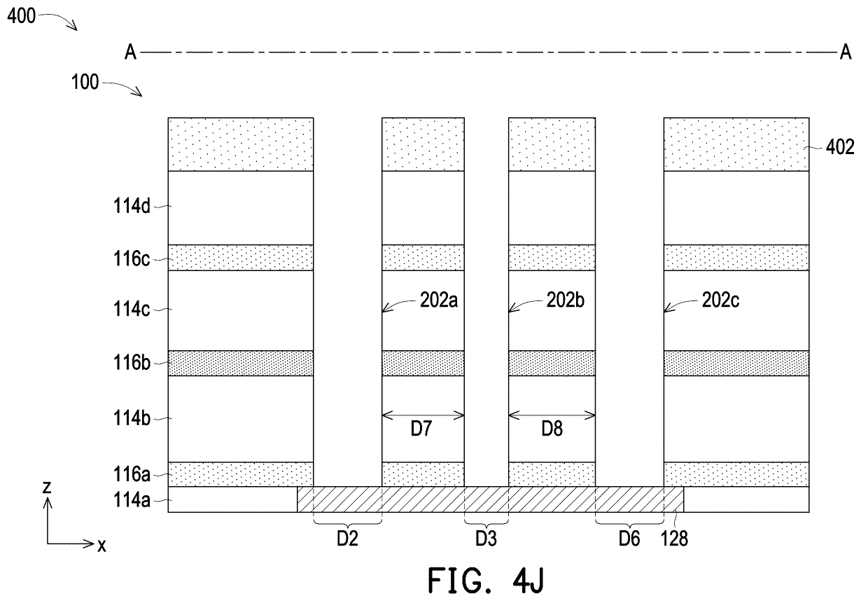

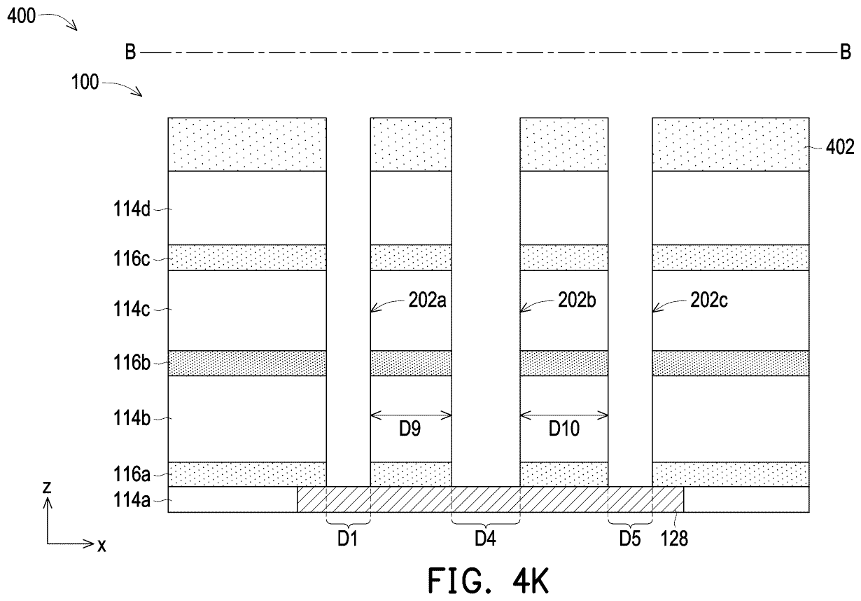

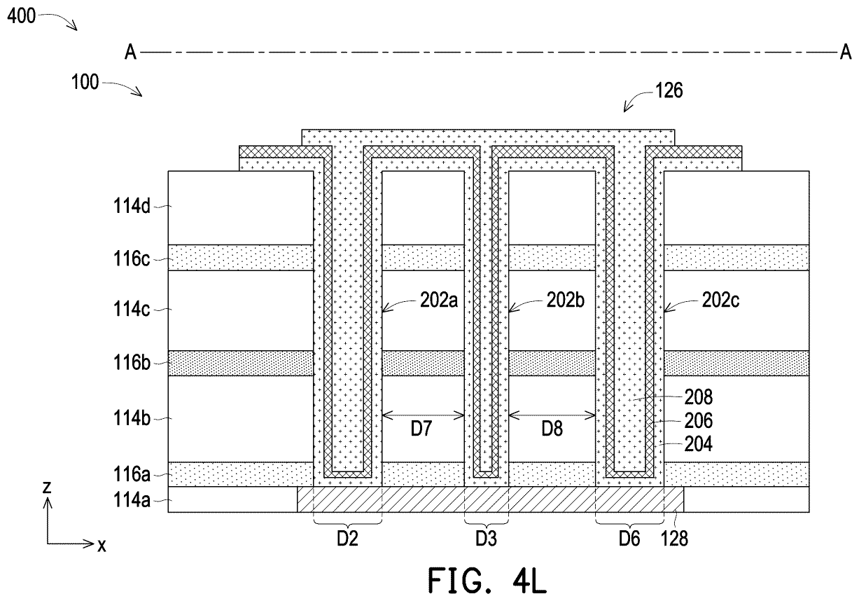

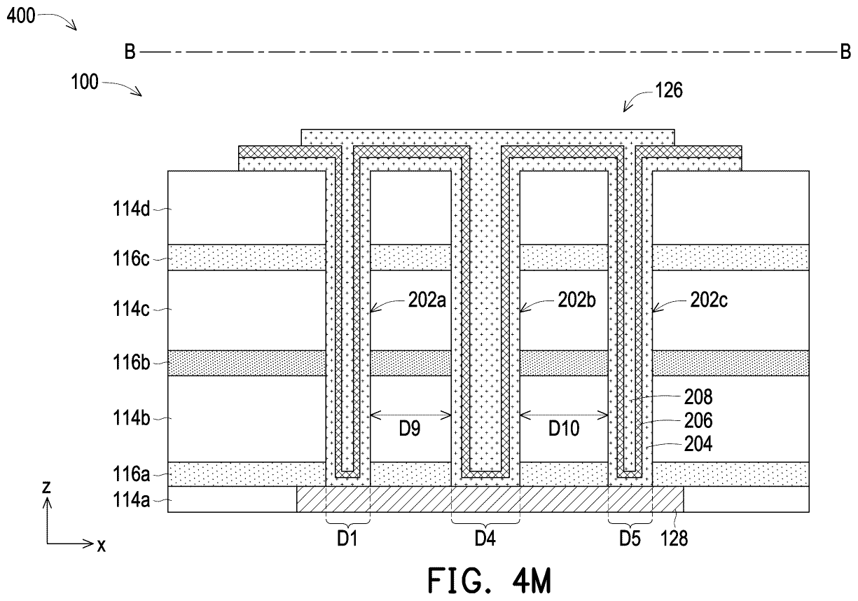

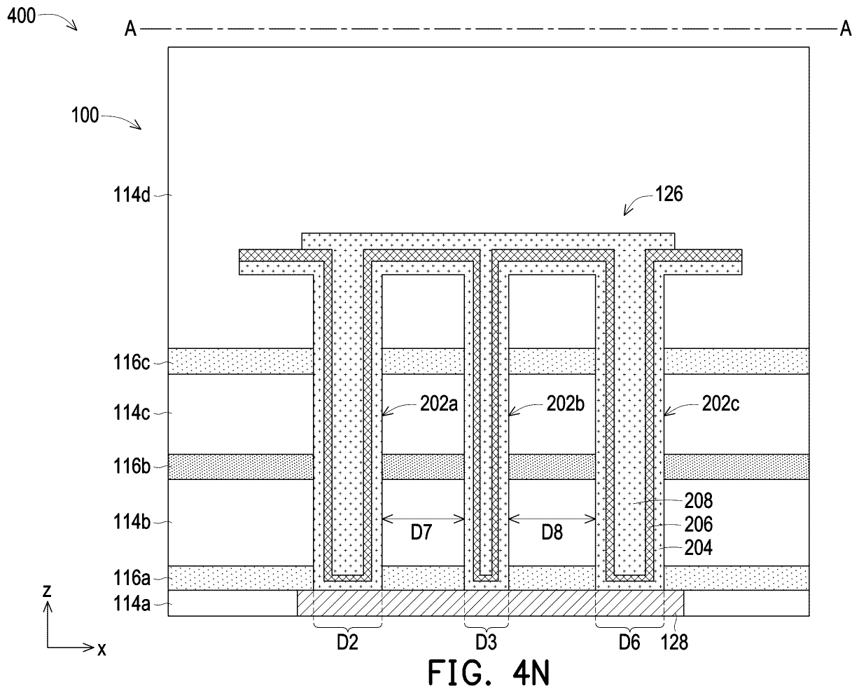

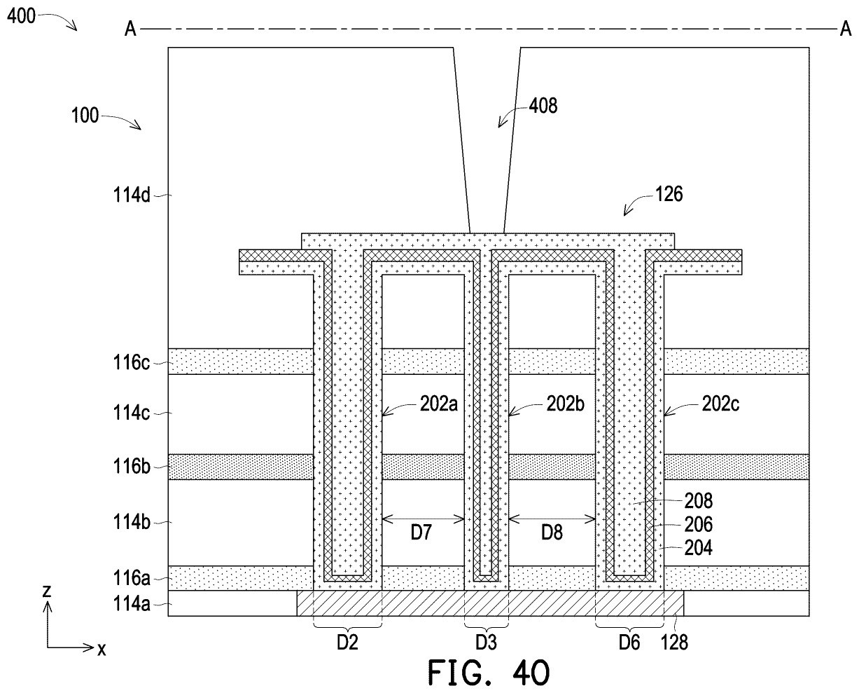

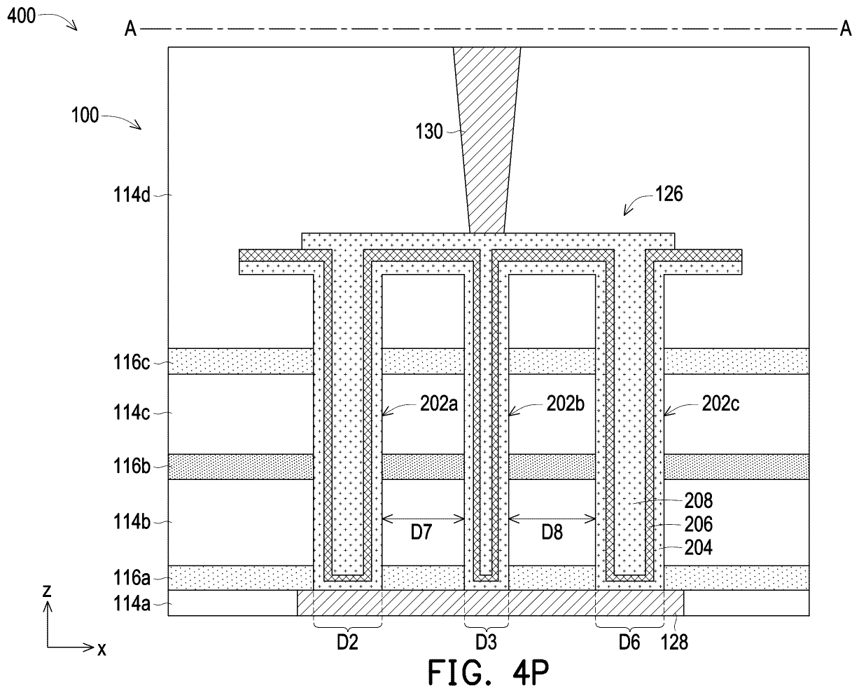

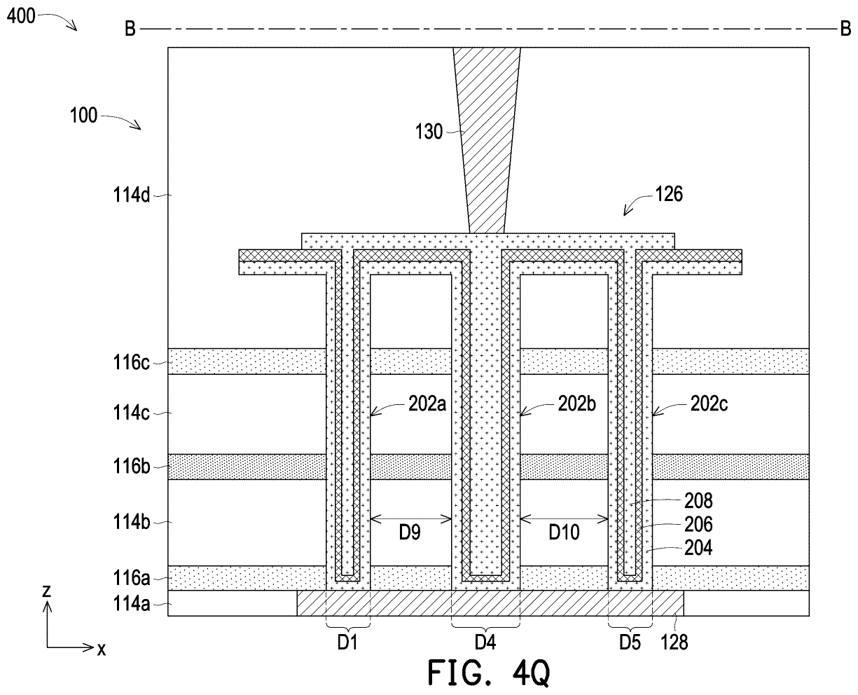

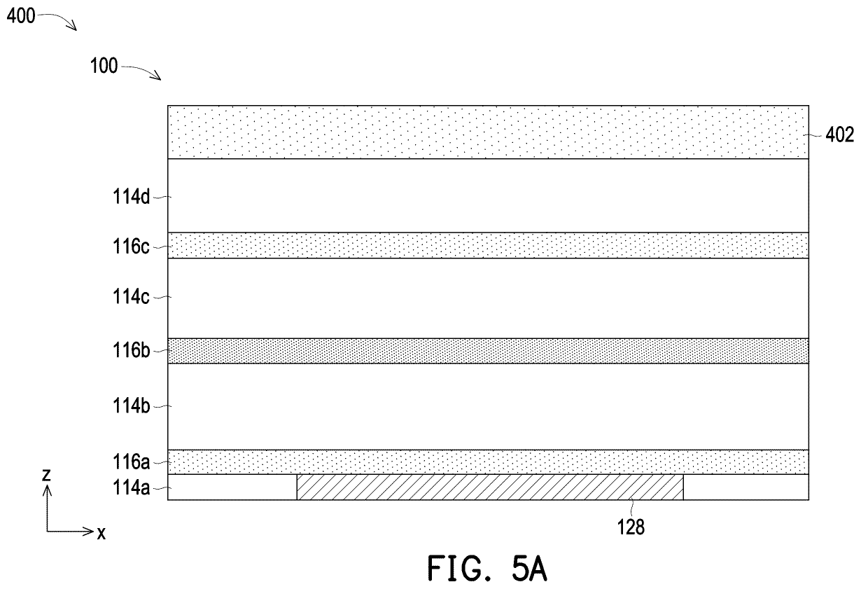

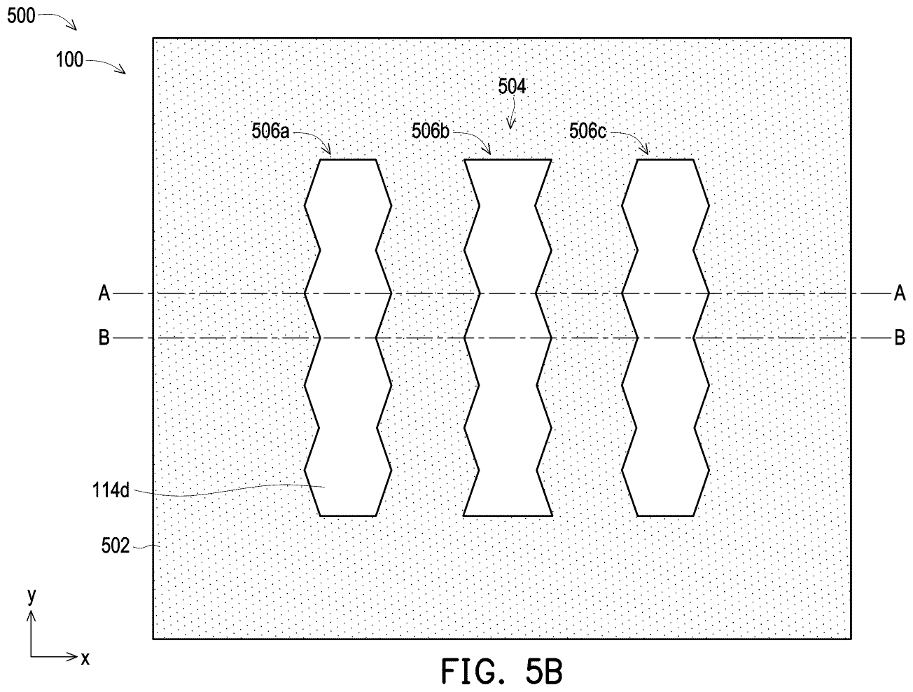

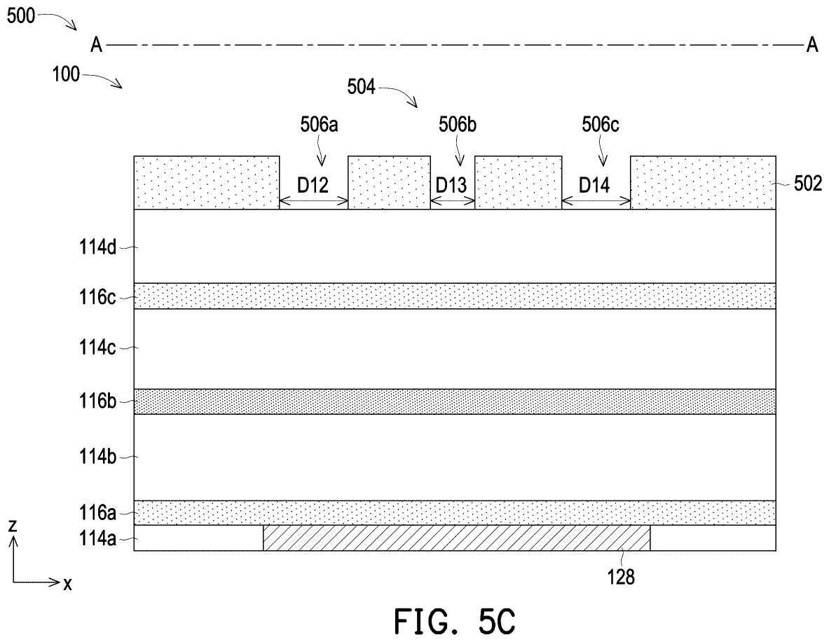

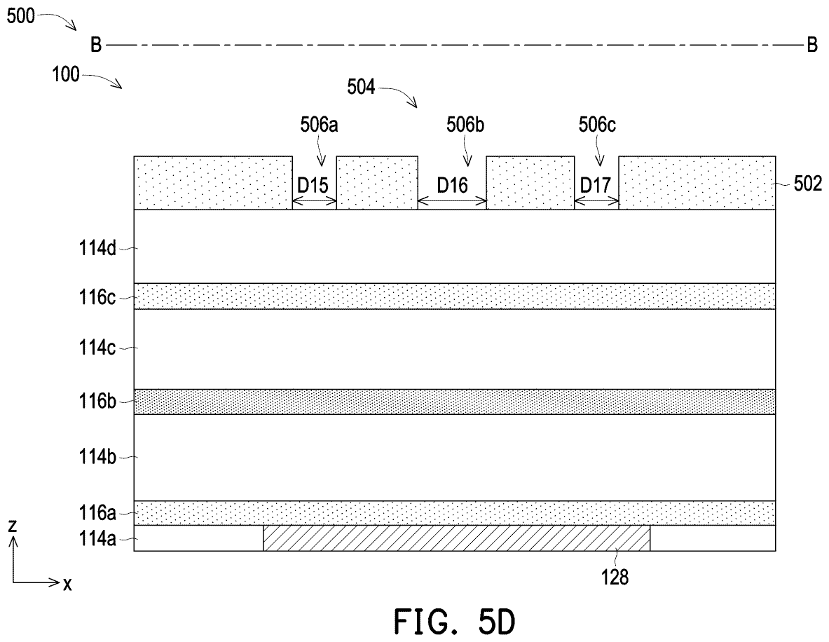

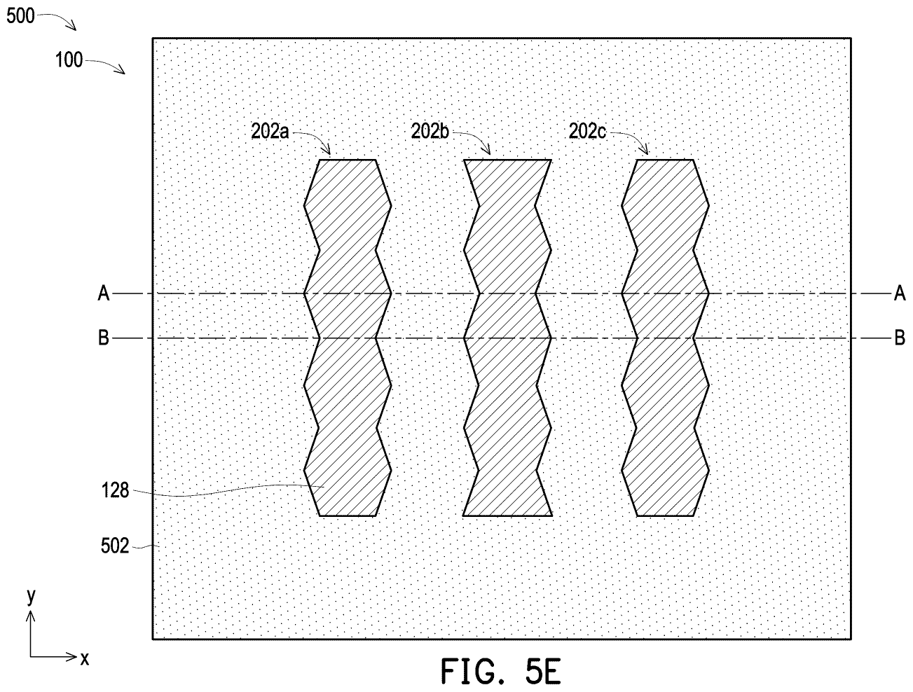

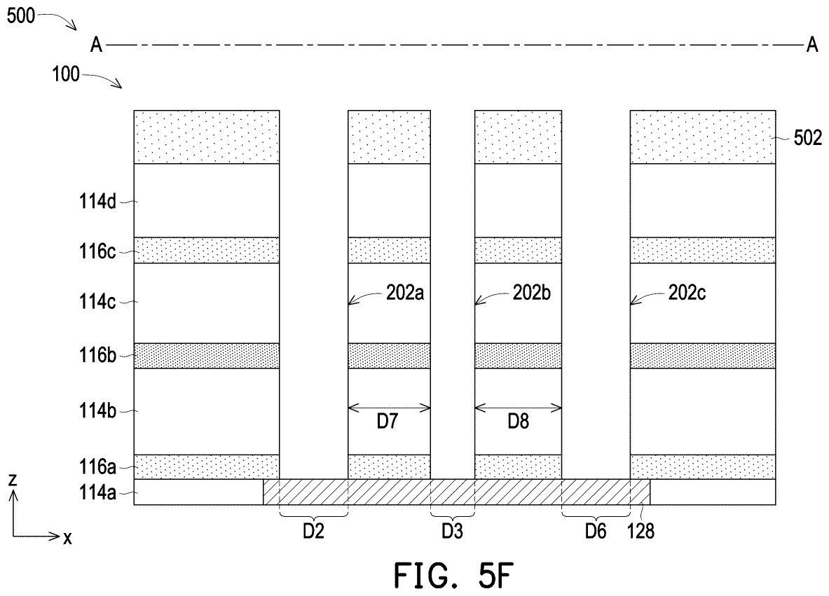

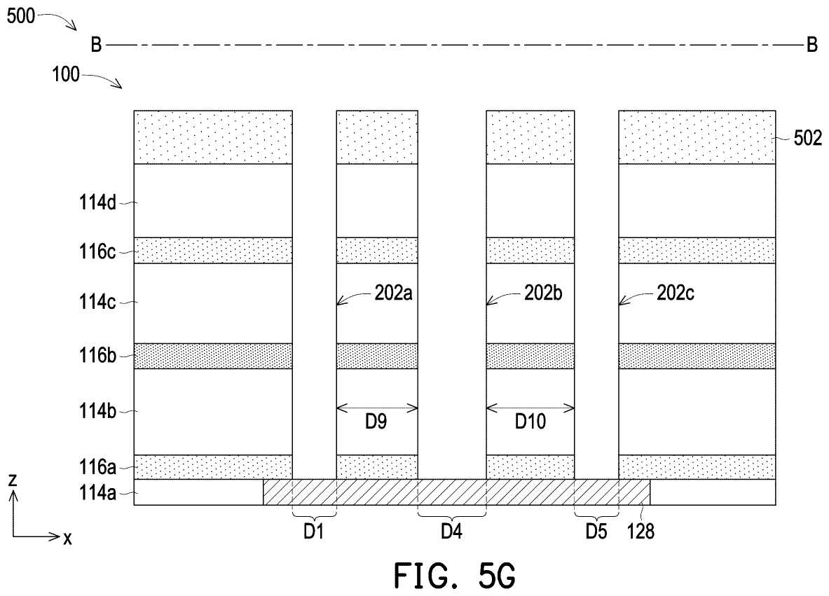

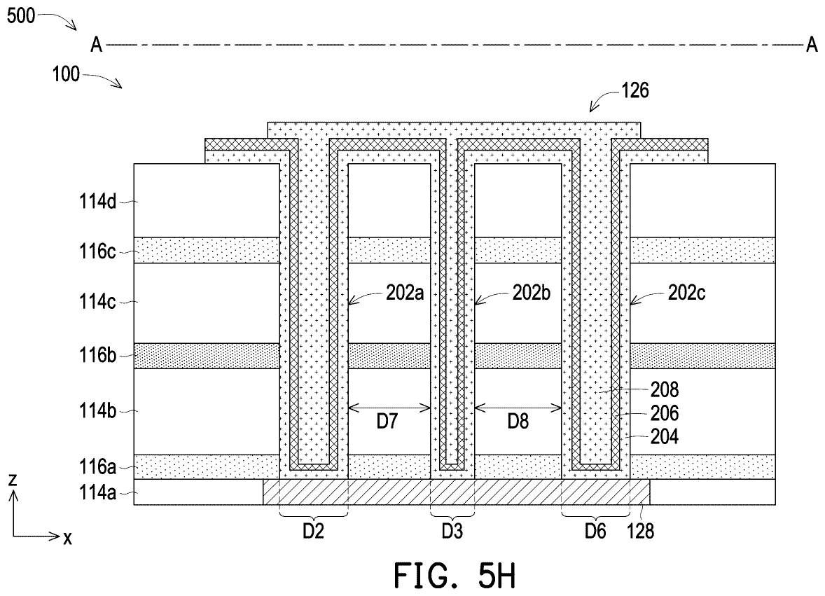

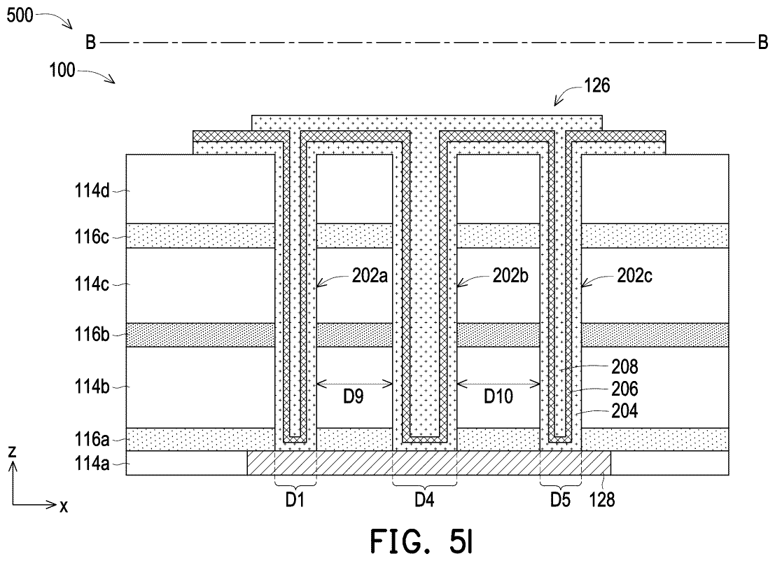

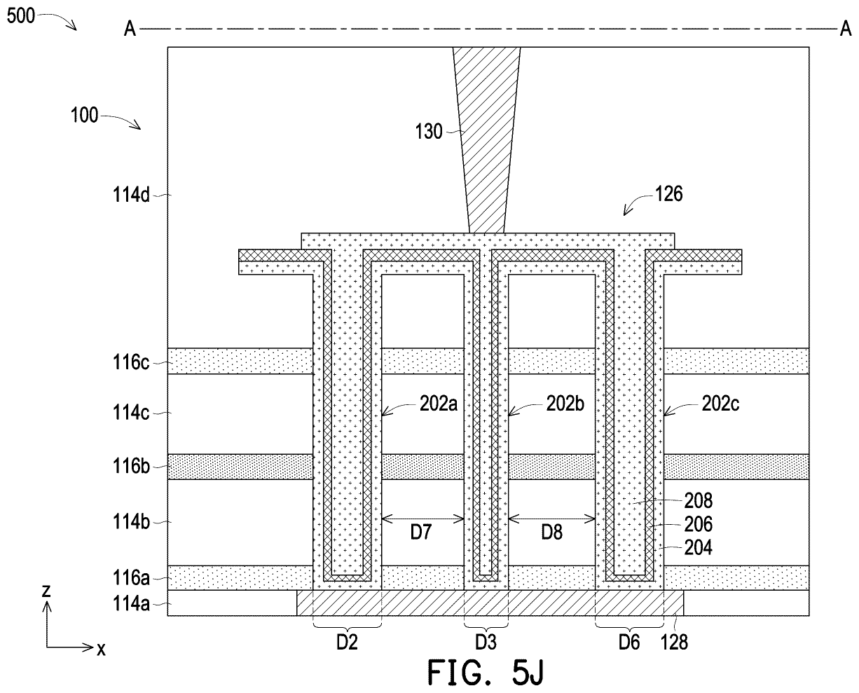

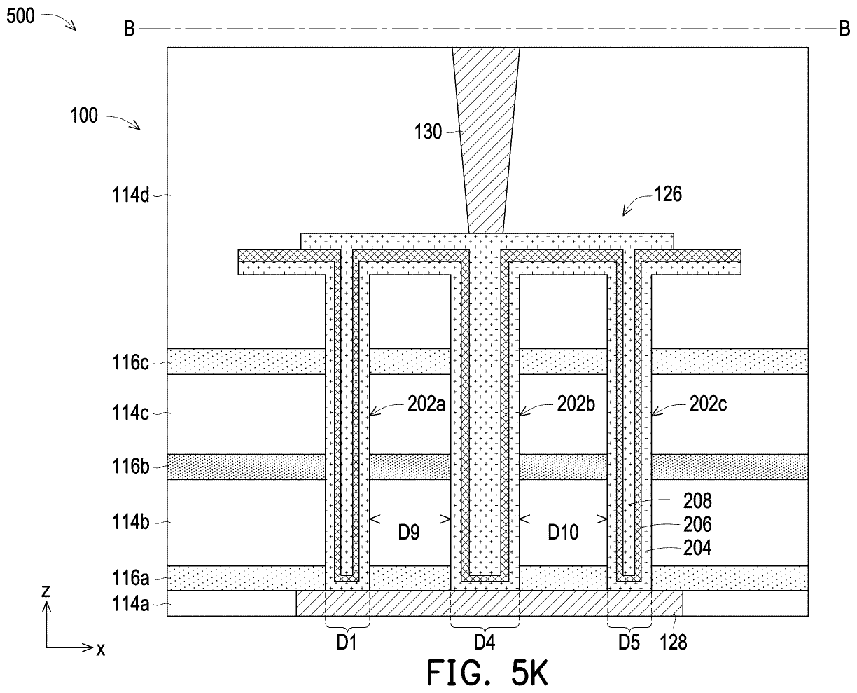

As shown in FIG. 3D, a trench capacitor structure 126 may be formed in one or more dielectric layers in the interconnect layer 104. The trench capacitor structure 126 may be formed such that the trenches 202a-202c of the trench capacitor structure 126 land on the bottom contact 128 in the interconnect layer 104. Example processes for forming the trench capacitor structure 126 are illustrated and described in connection with FIGS. 4A-4Q and 5A-5K.

As shown in FIG. 3E, a second portion of the interconnect layer 104 of the semiconductor device 100 is formed above the first portion of the interconnect layer 104, including above the trench capacitor structure 126. The second portion of the interconnect layer 104 may be formed in a similar manner as the first portion of the interconnect layer 104 as described in connection with FIG. 3C. The top contact 130 of the trench capacitor structure 126 may be formed in the second portion of the interconnect layer 104.

As indicated above, FIGS. 3A-3E are provided as an example. Other examples may differ from what is described with regard to FIGS. 3A-3E.

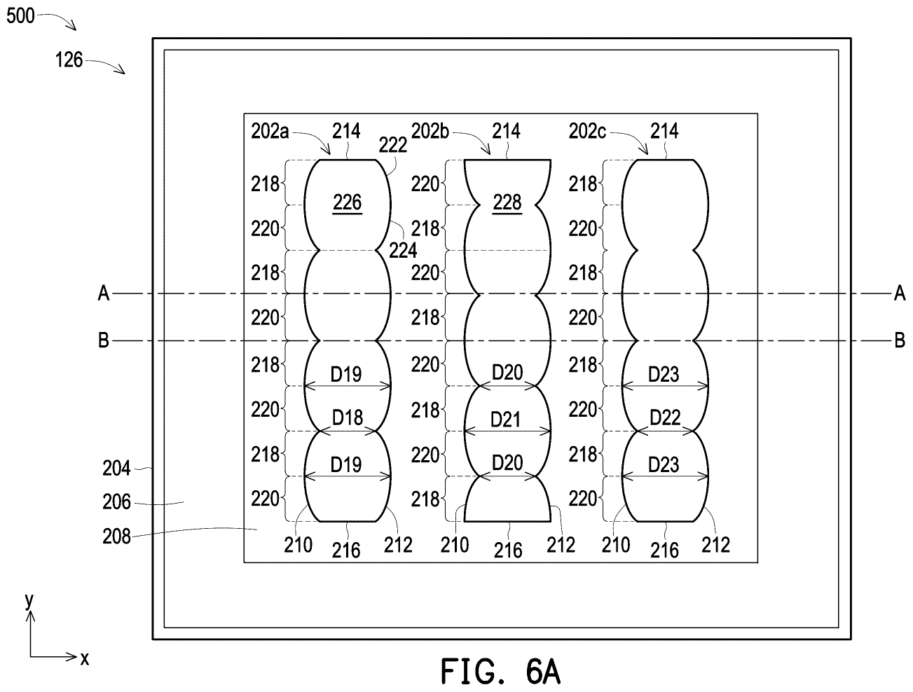

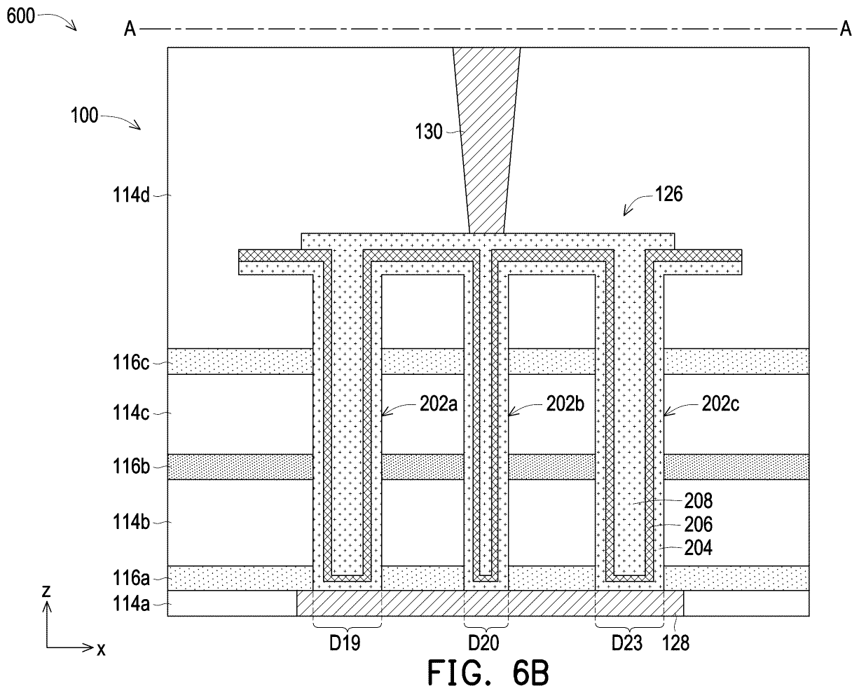

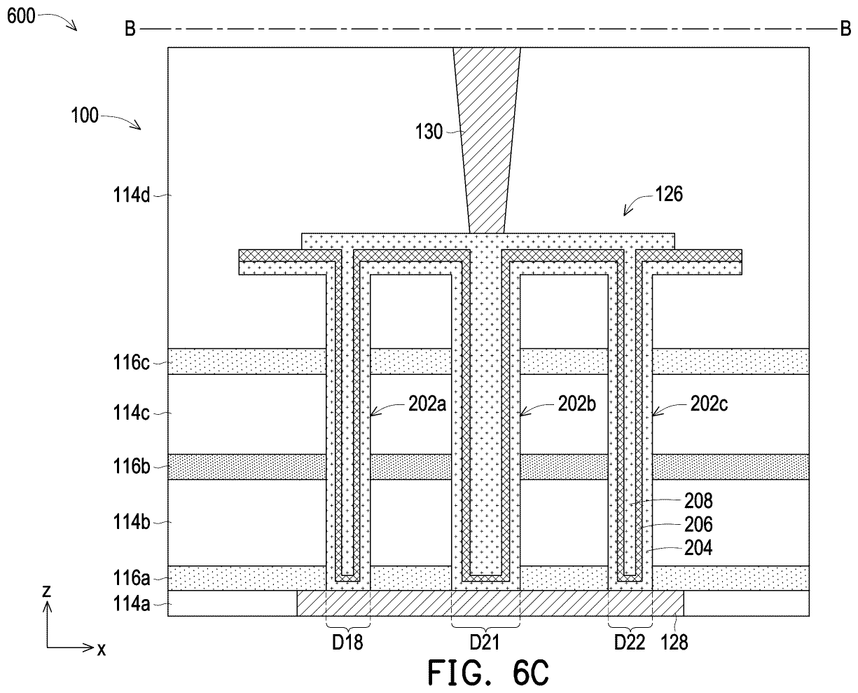

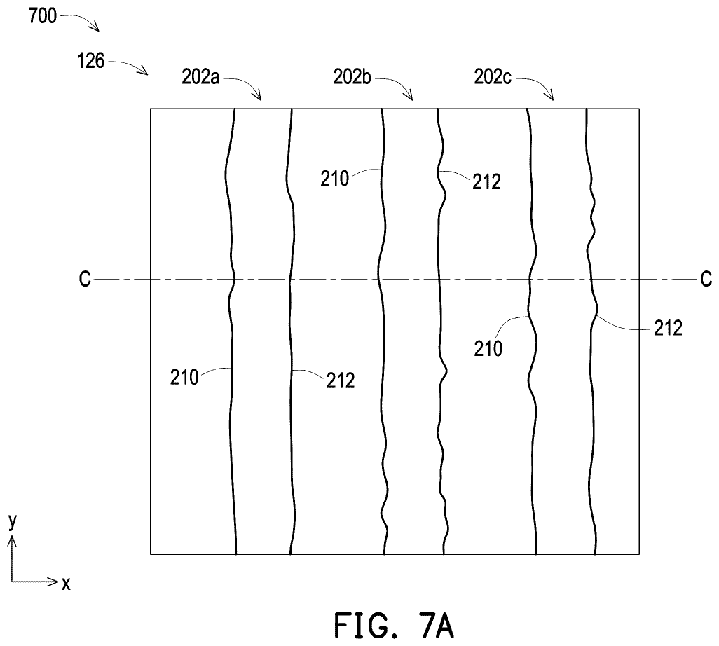

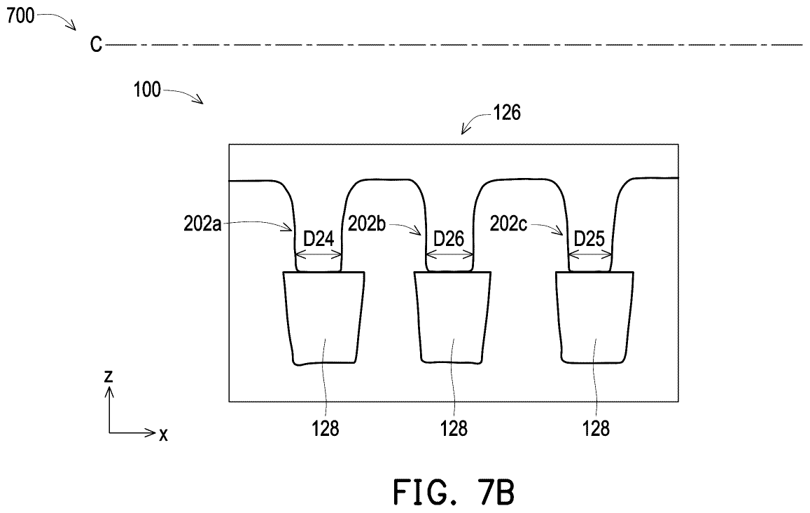

FIGS. 4A-4Q are diagrams of an example implementation 400 of forming a trench capacitor structure 126 described herein. While the semiconductor processing operations described in connection with FIGS. 4A-4Q are illustrated in connection with the example implementation 200 of the trench capacitor structure 126, the semiconductor processing operations described in connection with FIGS. 4A-4Q may be performed to form other implementations of other trench capacitor structure 126 that have non-uniform top view trench widths, such as an example implementation 600 of a trench capacitor structure 126 in FIGS. 6A-6C, and/or an example implementation 700 of a trench capacitor structure 126 in FIGS. 7A and 7B, among other examples.

In some implementations, one or more of the semiconductor processing operations described in connection with FIGS. 4A-4Q may be performed using one or more semiconductor processing tools, such as a deposition tool, an exposure tool, a developer tool, an etch tool, a planarization tool, a wafer/die transport tool, and/or another type of semiconductor processing tool. In some implementations, one or more of the semiconductor processing operations described in connection with FIGS. 4A-4Q may be performed as part of the process for forming the semiconductor device 100 described in connection with FIGS. 3A-3E.

As shown in FIG. 4A, a masking layer 402 may be formed on the ILD layer 114d in the interconnect layer 104 of the semiconductor device 100. The masking layer 402 may include a dielectric material such as a silicon oxynitride material (SiON) and/or another suitable dielectric material. Additionally and/or alternatively, the masking layer 402 may include a polymer material, such as an organic polymer material and/or an inorganic polymer material.

A deposition tool may be used to deposit the material of the masking layer 402 using a CVD technique, a PVD technique, an ALD technique, an electroplating technique, a dispensing technique, a spin-coating technique, and/or another suitable deposition technique. In some implementations, a planarization tool is used to perform a planarization operation (e.g., a CMP operation) to planarize the masking layer 402 after the masking layer 402 is deposited.

As shown in FIGS. 4B and 4C, a pattern 404 may be formed in the masking layer 402. The pattern 404 may include a plurality of openings 406a-406c through the masking layer 402. To form the pattern 404 in the masking layer 402, a deposition tool may be used to form a photoresist layer on the masking layer 402 (e.g., using a spin-coating technique or another suitable deposition technique). In some implementations, a bottom antireflective coating (BARC) is first deposited on the masking layer 402, and then the photoresist layer is deposited onto the BARC. An exposure tool may be used to expose the photoresist layer to a radiation source to pattern the photoresist layer. A developer tool may be used to develop and remove portions of the photoresist layer to expose the pattern 404.

An etch tool may be used to etch the masking layer 402 based on the pattern 404 in the photoresist layer to transfer the pattern 404 to the masking layer 402. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique).

As shown in FIGS. 4D and 4E, another etch operation is performed to etch through the ILD layers 114b, 114c, 114d, and through the ESLs 116b and 116c to form the trenches 202a-202c of the trench capacitor structure 126. The ILD layers 114b, 114c, 114d, and the ESLs 116b and 116c may be etched through the openings 406a-406c in the masking layer 402 to form the trenches 202a-202c.

In some implementations, a plurality of etch operations are performed to form the trenches 202a-202c of the trench capacitor structure 126. FIGS. 4D and 4E illustrate the trenches 202a-202c after a first etch operation (referred to as a “main etch” or ME operation), which may be performed to form the trenches 202a-202c to the ESL 116a. In other words, etching in the first etch operation stops at the ESL 116a such that the ESL 116a remains between the bottom of the trenches 202a-202c and the underlying bottom contact 128. The ESL 116a is kept over the bottom contact 128 to prevent the bottom contact 128 from being exposed to oxygen and other contaminants that might otherwise result in oxidation of the bottom contact 128.

In some implementations, the first etch operation may include a first plasma-based dry etch operation in which an oxide etchant such as a fluorine-based etchant (e.g., a carbon fluoride-based (CFₓ such as CF₄) gas etchant) is used. In some implementations, a plasma power level for the first plasma-based dry etch operation is included in a range of approximately 300 watts to approximately 500 watts. However, other values for the range are within the scope of the present disclosure.

FIGS. 4F-4H illustrate the trenches 202a-202c after a second etch operation (referred to as an “over etch” or OE operation), which may be performed after the first etch operation to shape the trenches 202a-202c. In particular, the second etch operation may be performed to create an irregular top view profile for the trenches 202a-202c. This results in one or more of the trenches 202a-202c having a non-uniform top view width in the x-direction along the length of one or more of the trenches 202a-202c.

In some implementations, the second etch operation may include a second plasma-based dry etch operation in which an oxide etchant such as a fluorine-based etchant (e.g., a carbon fluoride-based (CFₓ such as CF₄) gas etchant) is used. In some implementations, a plasma power level for the second plasma-based dry etch operation is different from the plasma power level used for the first plasma-based dry etch operation. In particular, the second plasma-based dry etch operation may be greater than the plasma power level used for the first plasma-based dry etch operation. For example, the plasma power level used in the second plasma-based dry etch operation may be included in a range of approximately 1400 watts to approximately 2000 watts. The greater plasma power level used in the second plasma-based dry etch operation enables the irregular top view profile to be achieved for the trenches 202a-202c without fully etching through the masking layer 402 in areas not exposed through the openings 406a-406c. However, other values for the range are within the scope of the present disclosure.

As shown in FIGS. 41-4K, a third etch operation (referred to as a “linear removal” or LRM etch operation) is performed to etch through the ESL 116a at the bottom of the trenches 202a-202c to extend the trenches 202a-202c through the ESL 116a and to the underlying bottom contact 128. Thus, the bottom contact 128 is exposed through the trenches 202a-202c after the third etch operation. The third etch operation may be performed using a fluorine-based etchant, such as a carbon fluoride-based (CFₓ such as CF₄) gas etchant.

As shown in FIGS. 4L-4N, the bottom electrode layer 204 may be deposited on the sidewalls and on the bottom surfaces (which correspond to the top surface of the bottom contact 128) of the trenches 202a-202c. The bottom electrode layer 204 may also be deposited on the ILD layer 114d between adjacent trenches 202a-202c. In some implementations, a deposition tool is used to conformally deposit the bottom electrode layer 204 such that the bottom electrode layer 204 conforms to the profile of the trenches 202a-202c. In some implementations, a conformal CVD technique and/or an ALD technique is used to deposit the bottom electrode layer 204.

As further shown in FIGS. 4L-4N, the insulator layer 206 may be deposited on the bottom electrode layer 204. Thus, the insulator layer 206 is deposited on the sidewalls and on the bottom surfaces (which correspond to the top surface of the bottom contact 128) of the trenches 202a-202c. The insulator layer 206 may also be deposited on the ILD layer 114d between adjacent trenches 202a-202c. In some implementations, a deposition tool is used to conformally deposit the insulator layer 206 such that the insulator layer 206 conforms to the profile of the trenches 202a-202c. In some implementations, a conformal CVD technique and/or an ALD technique is used to deposit the insulator layer 206.

As further shown in FIGS. 4L and 4M, the top electrode layer 208 may be deposited on the insulator layer 206. The top electrode layer 208 may be deposited such that the top electrode layer 208 fills the remaining areas of the trenches 202a-202c. The top electrode layer 208 may also be deposited on the ILD layer 114d between adjacent trenches 202a-202c. In some implementations, a deposition tool is used to conformally deposit the top electrode layer 208 using a PVD technique, a CVD technique, an ALD technique, and/or another suitable deposition technique.

As shown in FIG. 4N, additional material of the ILD layer 114d may be formed to encapsulate the trench capacitor structure 126. A deposition tool may be used to deposit the additional material of the ILD layer 114d using a PVD technique, an ALD technique, a CVD technique, an epitaxy technique, an oxidation technique, and/or another suitable deposition technique. The additional material of the ILD layer 114d may be deposited in one or more deposition operations. In some implementations, a planarization tool may be used to perform a planarization operation (e.g., a CMP operation) to planarize the ILD layer 114d after the additional material of the ILD layer 114d is deposited.

As shown in FIG. 4O, a recess 408 may be formed in the ILD layer 114d to the top electrode layer 208 of the trench capacitor structure 126. Thus, the top electrode layer 208 may be exposed through the recess 408. In some implementations, a pattern in a photoresist layer is used to etch the ILD layer 114d. In these implementations, a deposition tool may be used to form the photoresist layer on the ILD layer 114d. An exposure tool may be used to expose the photoresist layer to a radiation source to pattern the photoresist layer. A developer tool may be used to develop and remove portions of the photoresist layer to expose the pattern. An etch tool may be used to etch the ILD layer 114d based on the pattern to form the recess 408. In some implementations, one or more etch operations are performed to etch the ILD layer 114d. In some implementations, the one or more etch operations may include a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess 408 based on a pattern.

As shown in FIGS. 4P and 4Q, the top contact 130 may be formed in the recess 408. A deposition tool may be used to deposit the material of the top contact 130 using a CVD technique, a PVD technique, an ALD technique, an electroplating technique, and/or another suitable deposition technique. The top contact 130 may be deposited in one or more deposition operations. In some implementations, a seed layer is first deposited, and the top contact 130 is deposited on the seed layer. In some implementations, a planarization tool is used to perform a planarization operation (e.g., a CMP operation) to planarize the top contact 130 after the top contact 130 is deposited.

As indicated above, FIGS. 4A-4Q are provided as an example. Other examples may differ from what is described with regard to FIGS. 4A-4Q.

FIGS. 5A-5K are diagrams of an example implementation 500 of forming a trench capacitor structure 126 described herein. While the semiconductor processing operations described in connection with FIGS. 5A-5K are illustrated in connection with the example implementation 200 of the trench capacitor structure 126, the semiconductor processing operations described in connection with FIGS. 5A-5K may be performed to form other implementations of other trench capacitor structures 126 that have non-uniform top view trench widths, such as the example implementation 600 of a trench capacitor structure 126 in FIGS. 6A-6C, and/or the example implementation 700 of a trench capacitor structure 126 in FIGS. 7A and 7B, among other examples.

In some implementations, one or more of the semiconductor processing operations described in connection with FIGS. 5A-5K may be performed using one or more semiconductor processing tools, such as a deposition tool, an exposure tool, a developer tool, an etch tool, a planarization tool, a wafer/die transport tool, and/or another type of semiconductor processing tool. In some implementations, one or more of the semiconductor processing operations described in connection with FIGS. 5A-5K may be performed as part of the process for forming the semiconductor device 100 described in connection with FIGS. 3A-3E.

As shown in FIG. 5A, the masking layer 402 may be formed on the ILD layer 114d in a similar manner as described in connection with FIG. 4A.

As shown in FIGS. 5B-5D, a pattern 504 is formed in the masking layer 402 in a similar manner as the pattern 404 described in connection with FIGS. 4B and 4C. However, the pattern 504 includes openings 506a-506c that have irregular top view profiles. In particular, the openings 506a-506c have non-uniform widths along the y-direction. As shown in a cross-section view in FIG. 5C along the line A-A in FIG. 5B, the opening 506a may have an x-direction width (indicated in FIG. 5C as a dimension D12) that is greater than an x-direction width (indicated in FIG. 5C as a dimension D13) of the opening 506b in the cross-section along the line A-A. Moreover, the opening 506c may have an x-direction width (indicated in FIG. 5C as a dimension D14) that is greater than the x-direction width (dimension D13) of the opening 506b in the cross-section along the line A-A.

As shown in a cross-section view in FIG. 5D along the line B-B in FIG. 5B, the opening 506a may have an x-direction width (indicated in FIG. 5D as a dimension D15) that is less than an x-direction width (indicated in FIG. 5D as a dimension D16) of the opening 506b in the cross-section along the line B-B. The x-direction width (dimension D15) of the opening 506a in the cross-section along the line B-B is less than the x-direction width (dimension D12) in the cross-section along the line A-A. Moreover, the opening 506c may have an x-direction width (indicated in FIG. 5D as a dimension D17) that is less than an x-direction width (dimension D16) of the opening 506b in the cross-section along the line B-B. The x-direction width (dimension D17) of the opening 506c in the cross-section along the line B-B is less than the x-direction width (dimension D14) in the cross-section along the line A-A. The x-direction width (dimension D16) of the opening 506b in the cross-section along the line B-B is greater than the x-direction width (dimension D13) in the cross-section along the line A-A.

As shown in FIGS. 5E-5G, one or more etch operations are performed to etch through the ILD layers 114b, 114c, 114d, and through the ESLs 116a, 116b, and 116c to form the trenches 202a-202c of the trench capacitor structure 126. The ILD layers 114b, 114c, 114d, and through the ESLs 116a, 116b, and 116c may be etched through the openings 506a-506c in the masking layer 502 to form the trenches 202a-202c. In this way, using the pattern 504 in the masking layer 402 enables the irregular top view profile to be achieved for the trenches 202a-202c. The irregular top view profile may correspond to the irregular top view profile illustrated in FIGS. 2A, 6A, 7A, and/or may include another irregular top view profile.

In some implementations, a plurality of etch operations are performed to form the trenches 202a-202c of the trench capacitor structure 126. For example, a first etch operation (e.g., an ME operation) may be performed to form the trenches 202a-202c to the ESL 116a based on the pattern 504 in the masking layer. A second etch operation (e.g., an OE operation) may be performed after the first etch operation to shape the trenches 202a-202c (e.g., to increase an aspect ratio and/or to increase the vertically of the sidewalls of the trenches 202a-202c). As another example, a third etch operation (e.g., an LRM etch operation) may be performed to etch through the ESL 116a at the bottoms of the trenches 202a-202c to extend the trenches 202a-202c through the ESL 116a and to the underlying bottom contact 128.

As shown in FIGS. 5H and 51, the bottom electrode layer 204, the insulator layer 206, and the top electrode layer 208 of the trench capacitor structure 126 may be formed in the recesses 20a-202c and on the ILD layer 114d in a similar manner as described in connection with FIGS. 4L-4N.

As shown in FIGS. 5J and 5K, the top contact 130 may be formed on the top electrode layer 208. To form the top contact 130, a recess 408 may be formed through the ILD layer 114d to the top electrode layer 208, and the top contact 130 may be formed in the recess 408, as described in connection with FIGS. 40-4Q.

As indicated above, FIGS. 5A-5K are provided as an example. Other examples may differ from what is described with regard to FIGS. 5A-5K.

FIGS. 6A-6C are diagrams of an example implementation 600 of a trench capacitor structure 126 described herein. The example implementation 600 of the trench capacitor structure 126 may be included in the interconnect layer 104 (or another region) of the semiconductor device 100 and/or another semiconductor device. Moreover, the trench capacitor structure 126 in FIGS. 6A-6C may be manufactured (e.g., to have a non-uniform top view width along the length of the trench capacitor structure 126) using techniques and processes described in connection with FIGS. 4A-4Q and/or 5A-5K, among other examples.

As shown in a top view in FIG. 6A, the example implementation 600 of a trench capacitor structure 126 is similar to the example implementation 200 of a trench capacitor structure 126 illustrated in FIG. 2A. For example, the trench capacitor structure 126 in the example implementation 600 includes trenches 202a-202c that have a non-uniform x-direction width along the length (e.g., along the y-direction) of the trenches 202a-202c between the opposing ends 214 and 216. However, in the example implementation 600 of a trench capacitor structure 126, the non-uniform x-direction width is achieved through the arrangement of the sidewalls 210 and/or 212 of the trenches 202a-202c in an approximate repeating semi-circle top view pattern as opposed to a repeating zig-zag pattern. Thus, the top view line segments 222 and 224 are curved line segments as opposed to straight line segments. This results in the top view sections 226 in which top view line segments 222 and 224 connect to form an approximate barrel top view shape, and results in the top view sections 228 in which top view line segments 222 and 224 connect to form an approximate hourglass top view shape.

Thus, the x-direction width of the trench 202a transitions between narrow parts of the trench 202a (where the x-direction width is indicated as a dimension D18) and wide parts of the trench 202a (where the x-direction width is indicated as a dimension D19) between the ends 214 and 216. Similarly, the x-direction width of the trench 202b transitions between narrow parts of the trench 202b (where the x-direction width is indicated as a dimension D20) and wide parts of the trench 202b (where the x-direction width is indicated as a dimension D21) between the ends 214 and 216, and the x-direction width of the trench 202c transitions between narrow parts of the trench 202c (where the x-direction width is indicated as a dimension D22) and wide parts of the trench 202c (where the x-direction width is indicated as a dimension D23) between the ends 214 and 216.

FIG. 6B illustrates a detailed cross-section view of the example implementation 600 of a trench capacitor structure 126 along the line A-A in FIG. 6A. FIG. 6C illustrates a detailed cross-section view of the example implementation 600 of a trench capacitor structure 126 along the line B-B in FIG. 6A.

As shown in FIG. 6B, in the cross-section view along the line A-A, the x-direction width of the trench 202a (dimension D19 in FIG. 6B) and the x-direction width of the trench 202c (dimension D23 in FIG. 6B) are greater than the x-direction width of the trench 202b (dimension D20 in FIG. 6B). As shown in FIG. 6C, in the cross-section view along the line B-B, the x-direction width of the trench 202a (dimension D18 in FIG. 6C) and the x-direction width of the trench 202c (dimension D22 in FIG. 6C) are less than the x-direction width of the trench 202b (dimension D21 in FIG. 6C).

As indicated above, FIGS. 6A-6C are provided as an example. Other examples may differ from what is described with regard to FIGS. 6A-6C. For example, one or more of the trenches 202a-202c may have a non-uniform x-direction width that results from trench sidewalls that have a non-uniform (or non-repeating) curved profile, or another type of non-uniform profile. Moreover, the top view profile of one or more of the trenches 202a-202c may have non-uniform (or non-repeating) top view sections.

FIGS. 7A and 7B are diagrams of an example implementation 700 of a trench capacitor structure 126 described herein. The example implementation 700 of the trench capacitor structure 126 may be included in the interconnect layer 104 (or another region) of the semiconductor device 100 and/or another semiconductor device. Moreover, the trench capacitor structure 126 in FIGS. 7A and 7B may be manufactured (e.g., to have a non-uniform top view width along the length of the trench capacitor structure 126) using techniques and processes described in connection with FIGS. 4A-4Q and/or 5A-5K, among other examples.

As shown in a top view in FIG. 7A, the example implementation 700 of a trench capacitor structure 126 is similar to the example implementation 200 of a trench capacitor structure 126 illustrated in FIG. 2A. For example, the trench capacitor structure 126 in the example implementation 700 includes trenches 202a-202c that have a non-uniform x-direction width along the length (e.g., along the y-direction) of the trenches 202a-202c. However, as shown in FIG. 7A, the sidewalls 210 and 212 of the trenches 202a-202c in the example implementation 700 of the trench capacitor structure 126 may be wavy and non-uniform such that the trenches 202a-202c each have an irregular and non-repeating top view shape.

In some implementations, a difference between a widest part of the trench 202a (or of the trench 202b, or of the trench 202c) and a narrowest part of the trench 202a (or of the trench 202b, or of the trench 202c) along the length of the trench 202a in the y-direction between the ends 214 and 216 is at least approximately 10% of an average of the top x-direction width (e.g., the x-direction width at the top of the trench) along the length of the trench 202a. Having a difference in x-direction width at the top of the trench 202a that is at least approximately 10% of the average of the top x-direction width along the length of the trench 202a ensures that the area of the sidewalls 210 and 212 is sufficiently increased over uniform straight-lined sidewalls to achieve an increase in capacitance (e.g., to achieve at least an approximate 2% or greater increase in capacitance) for the trench capacitor structure 126. Similarly for the trenches 202b and 202c. However, other values are within the scope of the present disclosure.

FIG. 7B illustrates a cross-section view along the line C-C in FIG. 7A. As shown in FIG. 7B, each of the trenches 202a-202c is included on a respective bottom contact 128. However, in other implementations, two or more of the trenches 202a-202c may be connected to the same bottom contact 128. In the cross-section view in FIG. 7B, the x-direction width of the trench 202a (dimension D24 in FIG. 7B) and the x-direction width of the trench 202c (dimension D25 in FIG. 7B) are greater than the x-direction width of the trench 202b (dimension D26 in FIG. 7B). However, in other cross-section views along the trenches 202a-202c the x-direction width of the trench 202b may be greater than the x-direction width of the trench 202a and/or may be greater than the x-direction width of the trench 202c.

As indicated above, FIGS. 7A and 7B are provided as an example. Other examples may differ from what is described with regard to FIGS. 7A and 7B.

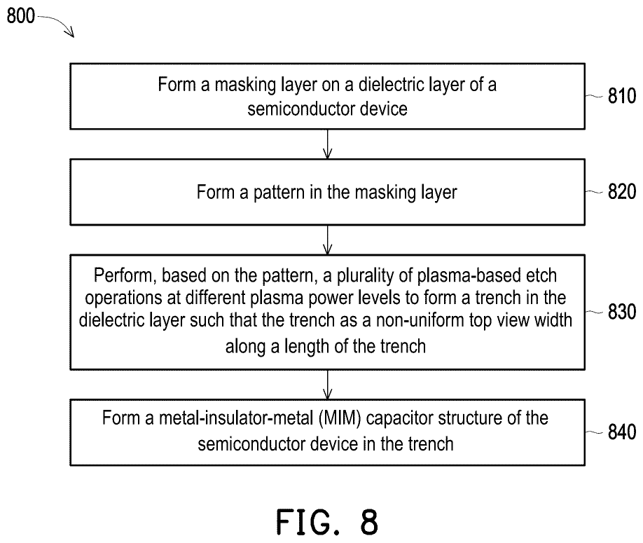

FIG. 8 is a flowchart of an example process 800 associated with forming a trench capacitor structure described herein. In some implementations, one or more process blocks of FIG. 8 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 8, process 800 may include forming a masking layer on a dielectric layer of a semiconductor device (block 810). For example, one or more semiconductor processing tools may be used to form a masking layer (e.g., a masking layer 402) on a dielectric layer (e.g., an ILD layer 114d) of a semiconductor device (e.g., a semiconductor device 100), as described herein.

As further shown in FIG. 8, process 800 may include forming a pattern in the masking layer (block 820). For example, one or more semiconductor processing tools may be used to form a pattern (e.g., a pattern 404) in the masking layer, as described herein.

As further shown in FIG. 8, process 800 may include performing, based on the pattern, a plurality of plasma-based etch operations at different plasma power levels to form a trench in the dielectric layer such that the trench as a non-uniform top view width along a length of the trench (block 830). For example, one or more semiconductor processing tools may be used to perform, based on the pattern, a plurality of plasma-based etch operations at different plasma power levels to form a trench (e.g., a trench 202a-202c) in the dielectric layer such that the trench as a non-uniform top view width along a length of the trench, as described herein.

As further shown in FIG. 8, process 800 may include forming an MIM capacitor structure of the semiconductor device in the trench (block 840). For example, one or more semiconductor processing tools may be used to form an MIM capacitor structure (e.g., a trench capacitor structure 126) of the semiconductor device in the trench, as described herein.

Process 800 may include additional implementations, such as any single implementation or any combination of implementations described below and/or in connection with one or more other processes described elsewhere herein.

In a first implementation, performing the plurality of plasma-based etch operations includes performing a first plasma-based etch operation at a first plasma power level to form the trench in the dielectric layer, and performing a second plasma-based etch operation at a second plasma power level to shape the top view of the trench such that the trench as the non-uniform top view width along the length of the trench, where the second plasma power level is different than the first plasma power level.

In a second implementation, alone or in combination with the first implementation, the second plasma power level is greater than the first plasma power level.

In a third implementation, alone or in combination with one or more of the first and second implementations, the first plasma power level is included in a range of approximately 300 watts to approximately 500 watts, and the second plasma power level is included in a range of approximately 1400 watts to approximately 2000 watts.

In a fourth implementation, alone or in combination with one or more of the first through third implementations, process 800 includes performing another etch operation after the plurality of plasma-based etch operations to etch through the dielectric layer to a conductive structure (e.g., a bottom contact 128), where forming the MIM capacitor structure includes forming a bottom electrode layer (e.g., a bottom electrode layer 204) on the conductive structure.

In a fifth implementation, alone or in combination with one or more of the first through fourth implementations, the trench includes a plurality of first sections of increasing top view width (e.g., top view sections 226 that increase in width from opposing ends of the top view sections 226 to a middle of the top view sections 226) and a plurality of second sections of decreasing top view width (e.g., top view sections 228 that decrease in width from opposing ends of the top view sections 228 to a middle of the top view sections 228).

In a sixth implementation, alone or in combination with one or more of the first through fifth implementations, the difference between the widest part of the trench and the narrowest part of the trench along the length of the trench is included in a range of approximately 10 nanometers to approximately 40 nanometers.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

In this way, a trench for a trench capacitor structure is formed to have a non-uniform top view width along the length of the trench. The non-uniform top view width results in the sidewalls of the trench having a zig-zag arrangement, a semi-circular or curved arrangement, or another non-straight-lined arrangement along the length of the trench. This provides a greater amount of surface area along the sidewalls for the electrode layers and insulator layer of the trench capacitor structure, thereby increasing the capacitance of the trench capacitor structure. In some implementations, the trench capacitor structure may include a plurality of trenches that each have a non-uniform top view width, and the arrangement of the trenches as well as the arrangement of the sidewalls of the trenches provide further increases in capacitance while maintaining minimum spacing between the trenches and without increasing (or with minimal increase to) the lateral footprint of the trench capacitor structure. The trenches of the trench capacitor structure may be formed to have non-uniform top view widths using various masking and etch techniques described herein.

As described in greater detail above, some implementations described herein provide a semiconductor device. The semiconductor device includes one or more dielectric layers. A trench is included in the one or more dielectric layers and has a non-uniform top width along a length of the trench between a first end and a second opposing end of the trench. A difference between a widest part of the trench and a narrowest part of the trench along the length of the trench is at least approximately 10% of an average of the top width along the length of the trench. The trench capacitor structure includes a bottom electrode layer along sidewalls and a bottom surface of the trench, an insulator layer on the bottom electrode layer, and a top electrode layer on the insulator layer.

As described in greater detail above, some implementations described herein provide a method. The method includes forming a masking layer on a dielectric layer of a semiconductor device. The method includes forming a pattern in the masking layer, performing, based on the pattern, a plurality of plasma-based etch operations at different plasma power levels to form a trench in the dielectric layer such that the trench as a non-uniform top view width along a length of the trench. The method includes forming an MIM capacitor structure of the semiconductor device in the trench.

As described in greater detail above, some implementations described herein provide a semiconductor device. The semiconductor device includes one or more dielectric layers. A trench is included in the one or more dielectric layers and has a plurality of sidewalls and a bottom surface connecting the plurality of sidewalls. A sidewall, of the plurality of sidewalls, includes a first plurality of top view line segments a second plurality of top view line segments arranged in an alternating manner along a length of the trench in a first direction, where the first plurality of top view line segments and the second plurality of top view line segments are mirrored in a second direction. The trench capacitor structure includes a bottom electrode layer along the plurality of sidewalls and on the bottom surface of the trench, an insulator layer on the bottom electrode layer, and a top electrode layer on the insulator layer.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
one or more dielectric layers having a trench formed therein,
wherein the trench has a non-uniform top width along a length of the trench between a first end and a second opposing end of the trench, and
wherein a difference between a widest part of the trench and a narrowest part of the trench along the length of the trench is at least approximately 10% of an average of the top width along the length of the trench; and
a trench capacitor structure, in the one or more dielectric layers, comprising:
a bottom electrode layer along sidewalls and a bottom surface of the trench;
an insulator layer on the bottom electrode layer; and
a top electrode layer on the insulator layer.

2. The semiconductor device of claim 1, wherein the difference between the widest part of the trench and the narrowest part of the trench along the length of the trench is included in a range of approximately 10 nanometers to approximately 40 nanometers.

3. The semiconductor device of claim 1, wherein the trench comprises a first plurality of top view sections and a second plurality of top view sections alternating with the first plurality of top view sections along the length of the trench.

4. The semiconductor device of claim 3, wherein a first end of a first top view section, of the first plurality of top view sections, is laterally adjacent to a second top view section of the second plurality of top view sections; and
wherein a second end of the first top view section opposing the first end of the first top view section is laterally adjacent to a third top view section of the second plurality of top view sections.

5. The semiconductor device of claim 4, wherein the top width of the trench at the first end of the first top view section is greater than the top width of the trench at the second end of the first top view section.

6. The semiconductor device of claim 4, wherein the second end of the first top view section is laterally adjacent to a third end of the third top view section;
wherein a fourth end of the third top view section opposing the third end of the third top view section is laterally adjacent to a fourth top view section of the first plurality of top view sections; and
wherein the top width of the trench at the fourth end of the third top view section is greater than the top width of the trench at the third end of the third top view section.

7. The semiconductor device of claim 1, wherein a first sidewall of the sidewalls of the trench includes a zig-zag top view pattern along the length of the trench; and
wherein the trench capacitor structure further comprises:
another trench adjacent to the trench,
wherein the other trench has a second sidewall adjacent to the first sidewall of the trench, and
wherein the second sidewall has a same zig-zag top view pattern as the first sidewall.

8. A method, comprising:
forming a masking layer on a dielectric layer of a semiconductor device;
forming a pattern in the masking layer;
performing, based on the pattern, a plurality of plasma-based etch operations at different plasma power levels to form a trench in the dielectric layer such that the trench as a non-uniform top view width along a length of the trench; and
forming a metal-insulator-metal (MIM) capacitor structure of the semiconductor device in the trench.

9. The method of claim 8, wherein performing the plurality of plasma-based etch operations comprises:
performing a first plasma-based etch operation at a first plasma power level to form the trench in the dielectric layer; and
performing a second plasma-based etch operation at a second plasma power level to shape the top view of the trench such that the trench as the non-uniform top view width along the length of the trench,
wherein the second plasma power level is different than the first plasma power level.

10. The method of claim 9, wherein the second plasma power level is greater than the first plasma power level.

11. The method of claim 9, wherein the first plasma power level is included in a range of approximately 300 watts to approximately 500 watts; and
wherein the second plasma power level is included in a range of approximately 1400 watts to approximately 2000 watts.

12. The method of claim 8, further comprising:
performing another etch operation after the plurality of plasma-based etch operations to etch through the dielectric layer to a conductive structure,
wherein forming the MIM capacitor structure comprises:
forming a bottom electrode layer on the conductive structure.

13. The method of claim 8, wherein the trench comprises a plurality of first sections of increasing top view width and a plurality of second sections of decreasing top view width.

14. The method of claim 8, wherein a difference between the widest part of the trench and the narrowest part of the trench along the length of the trench is included in a range of approximately 10 nanometers to approximately 40 nanometers.

15. A semiconductor device, comprising:
one or more dielectric layers, having a trench formed therein,
wherein the trench has a plurality of sidewalls and a bottom surface connecting the plurality of sidewalls,
wherein a sidewall, of the plurality of sidewalls, comprises:
a first plurality of top view line segments; and
a second plurality of top view line segments arranged in an alternating manner along a length of the trench in a first direction,
wherein the first plurality of top view line segments and the second plurality of top view line segments are substantially mirrored in a second direction; and
a trench capacitor structure, in the one or more dielectric layers, comprising:
a bottom electrode layer along the plurality of sidewalls and on the bottom surface of the trench;
an insulator layer on the bottom electrode layer; and
a top electrode layer on the insulator layer.

16. The semiconductor device of claim 15, wherein the first plurality of top view line segments and the second plurality of top view line segments are arranged in a zig-zag top view pattern in the first direction.

17. The semiconductor device of claim 15, wherein the first plurality of top view line segments and the second plurality of top view line segments are arranged in a repeating semi-circle top view pattern in the first direction.

18. The semiconductor device of claim 15, wherein the trench comprises a plurality of curved top view sections arranged along the length of the trench.

19. The semiconductor device of claim 18, wherein the trench capacitor structure further comprises:
another trench adjacent to the trench,
wherein the other trench comprises a plurality of concave top view sections arranged along the length of the other trench.

20. The semiconductor device of claim 19, wherein a curved top view section of the plurality of convex top view sections is approximately aligned in the second direction with a concave top view section of the plurality of concave top view sections.
